(19) United States
(12) Patent Application Publication
(10) Pub. No.: US 2007/0007534 A1
(43) Pub. Date: Jan. 11, 2007

(54) Optical mask, method of manufacturing thin film transistor array substrate, and thin film transistor array substrate manufactured by the method

(76) Inventors: In-woo Kim, Yongin-si (KR); Young-goo Song, Suwon-si (KR); Min-sik Um, Seoul (KR); Byung-duk Yang, Suwon-si (KR); Min-wook Park, Ama-si (KR); Young-hoon Yoo, Cheonan-si (KR)

Correspondence Address: CANTOR COLBURN, LLP, 55 GRIFFIN ROAD SOUTH, BLOOMFIELD, CT, 06002, US

(21) Appl. No.: 11/471,768

(22) Filed: Jun. 21, 2006

(30) Foreign Application Priority Data
Jun. 21, 2005 (KR) 10-2005-0053668

(51) Int. Cl. G03F 1/00; G06F 17/50; H01L 29/04; H01L 29/15; H01L 31/036

(52) U.S. Cl. 257/72; 716/19; 430/5

(57) ABSTRACT

Provided are an optical mask, a method of manufacturing a thin film transistor array substrate using the optical mask, and a thin film transistor array substrate manufactured by the method. The method includes forming a data metal layer on a substrate, forming an insulating layer on the data metal layer, patterning a contact hole exposing a portion of the data metal layer and at least one contact projection projecting toward an interior of the contact hole by etching the insulating layer, and forming a pixel electrode or an auxiliary data line terminal electrically connected to the data metal layer through the contact hole and the contact projection.

This application claims priority to Korean Patent Application No. 10-2005-0053668, filed on Jun. 21, 2005 and all the benefits accruing therefrom under 35 U.S.C. §119, and the contents of which in its entirety are herein incorporated by reference.

### BACKGROUND OF THE INVENTION

1. Field of the Invention

The present invention relates to an optical mask, a method of manufacturing a thin film transistor array substrate using the optical mask, and a thin film transistor array substrate manufactured by the method. More particularly, the present invention relates to an optical mask for forming patterns with improved electrical contact characteristics, a method of manufacturing a thin film transistor array substrate using the optical mask, and a thin film transistor array substrate manufactured by the method.

2. Description of the Related Art

A liquid crystal display (“LCD”) is a type of flat panel display device, which has been currently used in an extensive manner. The LCD has two substrates provided with a plurality of electrodes, and a liquid crystal layer sandwiched between the substrates. A voltage is applied to the electrodes to allow liquid crystal molecules within the liquid crystal layer to be rearranged to adjust the amount of light transmitted there through.

Among such LCDs, a thin film transistor (“TFT”)-based LCD is now widely used, which includes two substrates with pixel electrodes on a first substrate and a common electrode on a second substrate and has TFTs for switching a voltage applied to the electrodes. A TFT array substrate is provided with TFTs, an interconnection structure including gate lines for scan signal transmission and data lines for image signal transmission, and gate pads and data pads for receiving scan signals and image signals from external sources and transmitting the received scan signals and image signals to the gate lines and the data lines, respectively. The pixel electrodes, which are electrically connected to the TFTs, are formed at pixel regions defined by an intersection between each of the gate lines and each of the data lines.

A protection film is interposed between pixel electrodes and data wires to prevent a short circuit. The protection film is formed with contact holes for electrically connecting the data wires to the pixel electrodes. The contact holes are formed by etching the protection film on the data wires. In this case, an undercut or a tapered angle of greater than 90 degrees may be created. Such an undercut or a tapered angle of greater than 90 degrees may prevent the data wires and the pixel electrodes from being electrically connected with each other or may disconnect the data wires and the pixel electrodes from each other, thereby degrading electrical characteristics of an interconnection structure and resulting in a low product yield.

### BRIEF SUMMARY OF THE INVENTION

The present invention provides an optical mask for forming a pattern with improved electrical contact characteristics.

The present invention also provides a method of manufacturing a thin film transistor (“TFT”) array substrate using the optical mask.

The present invention also provides a TFT array substrate manufactured by the method.

The above features and advantages of the present invention will become clear to those skilled in the art upon review of the following description.

According to exemplary embodiments of the present invention, there is provided an optical mask including a transparent substrate, a main light-shielding pattern formed on the substrate and defining a substantial shape of a pattern to be transferred onto a surface of a TFT array substrate, and at least one auxiliary light-shielding pattern projecting toward a transparent region defined by the main light-shielding pattern.

According to other exemplary embodiments of the present invention, there is provided a method of manufacturing a TFT array substrate, the method including forming a data metal layer on a substrate, forming an insulating layer on the data metal layer, patterning a contact hole exposing a portion of the data metal layer and at least one contact projection projecting toward an interior of the contact hole by etching the insulating layer, and forming a pixel electrode or an auxiliary data line terminal electrically connected to the data metal layer through the contact hole and the contact projection.

According to still other exemplary embodiments of the present invention, there is provided a thin film transistor array substrate including a data metal layer formed on a substrate, an insulating layer formed on the data metal layer and including a contact hole exposing a portion of the data metal layer and at least one contact projection projecting toward the contact hole, and a pixel electrode or an auxiliary data line terminal formed on the insulating layer and electrically connected to the data metal layer through the contact hole and the contact projection.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic plan view of an optical mask according to an exemplary embodiment of the present invention;

FIG. 2A is a perspective view of an exemplary contact hole and an exemplary contact projection formed using the exemplary embodiment of the optical mask of FIG. 1;

FIGS. 2B through 2D are respective sectional views taken along line B-B′, line C-C′, and line D-D′ of FIG. 2A;

FIG. 3 is a schematic plan view of an optical mask according to another exemplary embodiment of the present invention;

FIG. 4A is a perspective view of an exemplary contact hole and an exemplary contact projection formed using the exemplary embodiment of the optical mask of FIG. 3;

FIGS. 4B through 4D are respective sectional views taken along line B-B′, line C-C′, and line D-D′ of FIG. 4A;

FIG. 5 is a schematic plan view of an optical mask according to still another exemplary embodiment of the present invention;

FIG. 6A is a perspective view of an exemplary contact hole and an exemplary contact projection formed using the exemplary embodiment of the optical mask of FIG. 5;

FIGS. 6B and 6C are respective sectional views taken along line B-B′ and line C-C′ of FIG. 6A;

FIGS. 7A through 7C are schematic plan views of optical masks according to other exemplary embodiments of the present invention;

FIG. 8A is a circuit view of a thin film transistor (“TFT”) array substrate according to an exemplary embodiment of the present invention;

FIG. 8B is a sectional view taken along line B-B′ of FIG. 8A;

FIGS. 9A, 11A, and 12A are sequential circuit views illustrating an exemplary method of manufacturing an exemplary TFT array substrate according to an exemplary embodiment of the present invention;

FIGS. 9B and 10 are sequential process sectional views taken along line B-B′ of FIG. 9A;

FIG. 11B is a sectional view taken along line B-B′ of FIG. 11A;

FIGS. 12B and 13 are sequential process sectional views taken along line B-B′ of FIG. 12A;

FIG. 14A is a circuit view of a TFT array substrate according to another exemplary embodiment of the present invention;

FIG. 14B is a sectional view taken along line B-B′ of FIG. 14A;

FIGS. 15A, 17A, and 23A are sequential circuit views illustrating an exemplary method of manufacturing an exemplary TFT array substrate according to another exemplary embodiment of the present invention;

FIGS. 15B and 16 are sequential process sectional views taken along line B-B′ of FIG. 15A;

FIGS. 17B and 18 through 22 are sequential process sectional views taken along line B-B′ of FIG. 17A;

FIGS. 23B and 24 are sequential process sectional views taken along line B-B′ of FIG. 23A; and

FIGS. 25 through 31 are sequential sectional views, taken along line B-B′ of FIG. 14A, illustrating an exemplary method of manufacturing an exemplary TFT array substrate according to still another exemplary embodiment of the present invention.

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Exemplary embodiments of an optical mask according to the present invention and exemplary contact holes and exemplary contact projections formed using the optical mask will now be described more fully with reference to the accompanying drawings, in which exemplary embodiments of the invention are shown.

The exemplary optical masks, and exemplary contact holes and exemplary contact projections formed using the exemplary optical masks as will later be described, can be applied to all structures having contact holes connecting a lower layer and an upper layer.

For convenience of illustration, exemplary optical masks, and exemplary contact holes and exemplary contact projections formed using the exemplary optical masks will be illustrated in terms of exemplary applications for a thin film transistor (“TFT”) array substrate and a method of manufacturing the TFT array substrate. An exemplary TFT array substrate including an exemplary contact hole and an exemplary contact projection and an exemplary method of manufacturing the same will be further described below.

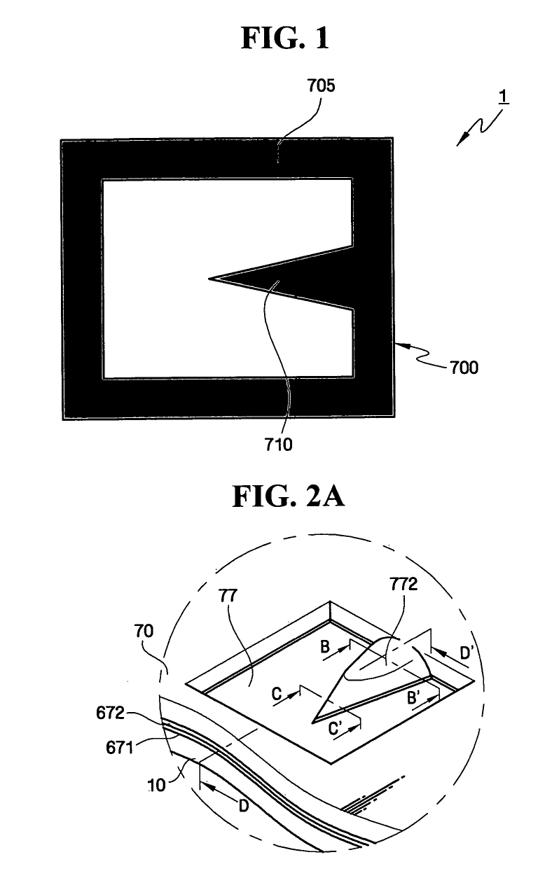

First, an optical mask 1 will be described with reference to FIG. 1.

Referring to FIG. 1, the optical mask 1 includes a transparent substrate 700, a main light-shielding pattern 705, and an auxiliary light-shielding pattern 710. The transparent substrate 700 is a light-transmitting substrate having thereon patterns for defining a transparent region and an opaque region. For example, a transparent quartz substrate, a transparent glass substrate, or the like may be used as the transparent substrate 700.

The main light-shielding pattern 705 is formed on the transparent substrate 700 and defines a substantial shape of a pattern to be transferred onto a surface of a TFT array substrate. The main light-shielding pattern 705 may define a shape having a closed periphery, thus defining an interior transparent region. The main light-shielding pattern 705 is formed on the transparent substrate 700 by coating an opaque material, e.g., chromium, iron oxide, and silicon thereon. That is, the main light-shielding pattern 705 formed on the transparent substrate 700 defines a light-shielding region with an opaque material coated thereon and a transparent region without an opaque material coated thereon.

The auxiliary light-shielding pattern 710 may be formed to project from the main light-shielding pattern 705 toward the transparent region defined by the main light-shielding pattern 705. That is, the auxiliary light-shielding pattern 710 may be formed in a projecting shape using an opaque material in the transparent region defined by the main light-shielding pattern 705. For example, the auxiliary light-shielding pattern 710 may be made of chromium, iron oxide, silicon, or the like. In the illustrated embodiment, the main light-shielding pattern 705 defines a substantially rectangular shaped pattern, and the auxiliary light-shielding pattern 710 protrudes from one side of the rectangular shaped pattern of the main light-shielding pattern 705 towards an interior of the rectangular shaped pattern. In the illustrated embodiment, the auxiliary light-shielding pattern 710 has a triangular shaped pattern, with one side of the triangular shaped pattern of the auxiliary light-shielding pattern 710 aligned with one side of the rectangular shaped pattern of the main light-shielding pattern 705. While particular shapes of patterns for the main light-shielding pattern 705 and the auxiliary light-shielding pattern 710 are illustrated, it should be understood that alternate embodiments of the optical mask 1 may include varying shapes. Also, while only one auxiliary light-shielding pattern 710 is illustrated in FIG. 1, more auxiliary light-shielding patterns may also be formed. At least a portion of the auxiliary light-shielding pattern 710 may be formed to a width smaller than the limiting resolution of an exposure machine, as will be further described below.

The main light-shielding pattern 705 and the auxiliary light-shielding pattern 710 may be formed so that the transparent region is defined as an opening. The transparent region defined as an opening is repeatedly patterned on the transparent substrate 700 according to the shape of a TFT array substrate.

The width of the auxiliary light-shielding pattern 710 may decrease in the direction of the transparent region from the main light-shielding pattern 705. That is, the width of the auxiliary light-shielding pattern 710 may decrease as it extends towards the interior region defined by the main light-shielding pattern 705, such that the auxiliary light-shielding pattern 710 has a greater width at a location where it abuts the main light-shielding pattern 705, and a smaller width at a location where it does not abut the main light-shielding pattern 705. In this case, the width of a portion of the auxiliary light-shielding pattern 710 contacting the main light-shielding pattern 705 may be greater than the limiting resolution of an exposure machine. However, since the width of the auxiliary light-shielding pattern 710 gradually decreases in the direction of the transparent region from the main light-shielding pattern 705, the width of a portion of the auxiliary light-shielding pattern 710 may be smaller than the limiting resolution of an exposure machine.

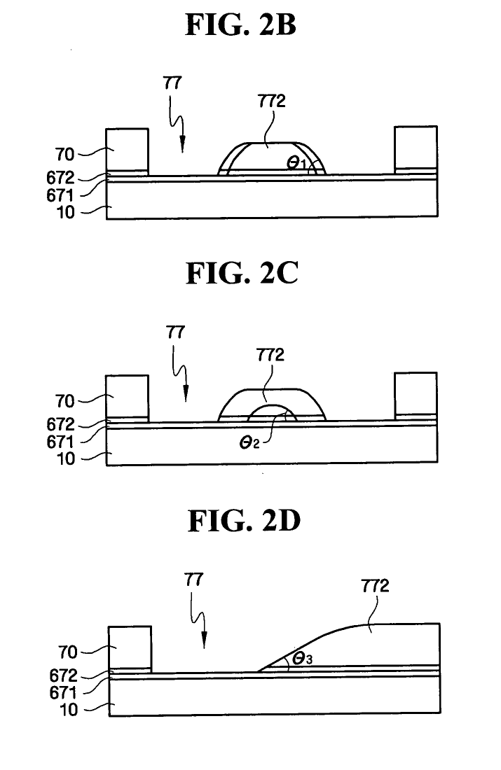

An exemplary contact hole and an exemplary contact projection formed using the exemplary optical mask 1 of FIG. 1 will now be described with reference to FIGS. 2A through 2D.

FIG. 2A is a perspective view of an exemplary contact hole and an exemplary contact projection formed using the exemplary embodiment of the optical mask of FIG. 1, and FIGS. 2B through 2D are respective sectional views taken along line B-B′, line C-C′, and line D-D′ of FIG. 2A.

Referring to FIGS. 2A through 2D, a data metal layer composed of a first data metal layer 671 and a second data metal layer 672 is formed on a substrate 10. The first data metal layer 671 may be formed on the substrate 10, and the second data metal layer 672 may be formed on the first data metal layer 671. The first data metal layer 671 may be made of chromium, molybdenum, titanium, or a compound thereof, and the second data metal layer 672 may be made of aluminum (Al) or its alloy, although alternate materials having suitable characteristics for a TFT array substrate may also be employed.

A protection film 70 is formed on the data metal layer, and may be formed on the second data metal layer 672. For example, the protection film 70 may be made of an organic material with good planarization property and photosensitivity, a low-dielectric insulating material such as a-Si:C:O or a-Si:O:F formed by plasma-enhanced chemical vapor deposition (“PECVD”), or an inorganic material such as silicon nitride (SiNx).

A contact hole 77 and a contact projection 772 are formed in the protection film 70. The contact hole 77 is formed on the data metal layer 671 and 672 so that a portion of the data metal layer 671 and 672 is exposed. In this case, the contact hole 77 may expose an upper surface of the first data metal layer 671, through a removal of a portion of the second data metal layer 672, as will be further described below. The contact projection 772 is formed to project toward the contact hole 77 from the protection film 70. A portion of the second data metal layer 672, as well as a portion of the first data metal layer 671, corresponding to the contact projection 772 is not exposed. One or more contact projections may be formed. The contact hole 77 and the contact projection 772 are formed in the protection film 70 to define an opening through which the data metal layer 671 and 672 is exposed.

Referring to FIG. 2A, the width and height of the contact projection 772 may decrease toward the inside of the contact hole 77. The contact projection 772 has a tapered angle of smaller than 90 degrees at its sidewall, which is perpendicular with respect to a projecting direction of the contact projection 772 in the contact hole 77. The tapered angle of the sidewall of the contact projection 772 gradually decreases toward the inside of the contact hole 77. That is, as shown in FIGS. 2B and 2C, the contact projection 772 has a tapered angle θ₂ at a lower location of the inside of the contact hole 77, which is smaller than a tapered angle θ₁ at a higher location of the inside of the contact hole 77, where the angles θ₁ and θ₂ represent the angles of the sidewall of the contact projection 772 with respect to a line extending perpendicular to the projecting direction of the contact projection 772 and lying substantially within a plane substantially parallel to a surface of the substrate 10.

Since the tapered angle of the sidewall of the contact projection 772 decreases toward the inside of the contact hole 77, the contact projection 772 comes into contact with the first data metal layer 671 in a state in which it slopes gently down to the first data metal layer 671. Therefore, a pixel electrode, as will be further described below, formed on the protection film 70 can be electrically connected to the first data metal layer 671 through the contact hole 77 and the contact projection 772 in a stable manner. Consequently, a disconnection does not occur, thereby ensuring better electrical characteristics than a connection between an electrode and the data metal layer 671 through a contact hole not having the contact projection 772.

Since the height of the contact projection 772 also decreases towards the inside or interior of the contact hole 77, the contact projection 772 has a tapered angle θ₃ of smaller than 90 degrees at its tip within the contact hole 77, as shown in FIG. 2D, where the angle θ₃ is measured between the sidewall of the tip of the contact projection 772 and the projecting direction of the contact projection 772. Thus, the contact projection 772 comes into contact with the first data metal layer 671 in a state in which it slopes gently toward the inside of the contact hole 77, and thus a pixel electrode can be electrically connected to the first data metal layer 671 through the contact hole 77 in a stable manner. Consequently, a disconnection does not occur, thereby ensuring better electrical characteristics than would otherwise occur in a contact hole not having the contact projection 772.

Hereinafter, an exemplary method of forming an exemplary contact hole and an exemplary contact projection using an optical mask according to an exemplary embodiment of the present invention will be described with reference to FIGS. 1 and 2A through 2D.

First, the first data metal layer 671 and the second data metal layer 672 are sequentially formed on the substrate 10. The first data metal layer 671 may be made of chromium, molybdenum, titanium, or a compound thereof, and the second data metal layer 672 may be made of aluminum (Al) or its alloy, although alternate materials having suitable characteristics for a TFT array substrate may also be employed.

Then, the protection film 70 is formed on the second data metal layer 672 and a photoresist film is coated on the protection film 70.

Then, a pattern on the optical mask 1 in which the width of the auxiliary light-shielding pattern 710 decreases in the direction of the transparent region from the main light-shielding pattern 705 is transferred onto the photoresist film coated on the protection film 70 by a reduction projection-type exposure method. In this case, the main light-shielding pattern 705 and the auxiliary light-shielding pattern 710 are light-shielding regions unlike the transparent region, and thus light cannot pass there through. However, a portion of the auxiliary light-shielding pattern 710 having a width smaller than the limiting resolution of the exposure machine used in the exposure method is not accurately patterned by a photoreceptor even through it is a light-shielding portion. That is, a predetermined light beam is transmitted through the portion of the auxiliary light-shielding pattern 710 having a width smaller than the limiting resolution due to light scattering. In this case, a large amount of light is scattered at a proximal portion of the auxiliary light-shielding pattern 710 to the transparent region, as compared to a distal portion of the auxiliary light-shielding pattern 710 disposed adjacent to the main light-shielding pattern 705.

Thus, polymers of the photoresist film corresponding to portions of the main light-shielding pattern 705 and the auxiliary light-shielding pattern 710 having a width greater than the limiting resolution are hardly decomposed but polymers of the photoresist film corresponding to the transparent region are completely decomposed. Polymers of the photoresist film corresponding to the portion of the auxiliary light-shielding pattern 710 having a width smaller than the limiting resolution are not completely decomposed, but are partially decomposed. In this case, more polymers are decomposed at a border between the transparent region and the portion of the auxiliary light-shielding pattern 710 having a width smaller than the limiting resolution, because a large amount of light is scattered at a proximal portion of the auxiliary light-shielding pattern 710 to the transparent region.

Then, a developing process is performed to remove a portion of the photoresist film exposed to light. In this case, a portion of the photoresist film having hardly any decomposed polymers and corresponding to the main light-shielding pattern 705 and the portion of the auxiliary light-shielding pattern 710 having a width greater than the limiting resolution is not removed, whereas a portion of the photoresist film having mostly decomposed polymers and corresponding to the transparent region is removed. However, a portion of the photoresist film corresponding to the portion of the auxiliary light-shielding pattern 710 having a width smaller than the limiting resolution is partially removed since a predetermined light beam is transmitted there through. In this case, as the width of the auxiliary light-shielding pattern 710 is much smaller than the limiting resolution, particularly at the tip of the auxiliary light-shielding pattern 710, a large amount of light is transmitted. In other words, a large amount of light is transmitted at a proximal portion of the auxiliary light-shielding pattern 710 to the transparent region. Thus, the thickness of the photoresist film decreases at the portion of the auxiliary light-shielding pattern 710 having a width smaller than the limiting resolution and at a proximal portion of the auxiliary light-shielding pattern 710 to the transparent region. That is, the portion of the auxiliary light-shielding pattern 710 is shaped such that the auxiliary light-shielding pattern 710 has a tapered angle of smaller than 90 degrees at its sidewall, which is perpendicular to a direction of the auxiliary light-shielding pattern 710 from the main light-shielding pattern 705 of the optical mask. The height of the photoresist film also gradually decreases in the direction of the transparent region from the main light-shielding pattern 705 of the optical mask 1.

Then, the protection film 70 is etched using a photoresist film pattern thus formed as an etching mask. The etching can be performed by plasma dry etching which includes injecting appropriate gases into a process chamber, forming plasma, and allowing ionized particles to collide with a wafer surface to remove a material by physical or chemical reaction. In this case, an etching gas may be SF₆, CF₄, O₂, or the like.

During the etching, the protection film 70 with the photoresist film removed is completely etched, and the protection film 70 is patterned according to the photoresist film pattern. Thus, a thinner photoresist film increases the etch rate of the protection film 70, whereas a thicker photoresist film decreases the etch rate of the protection film 70. That is, the protection film 70 can be patterned according to the photoresist film pattern.

Next, the second data metal layer 672 is etched. As previously described, the second data metal layer 672 may be made of aluminum (Al) or its alloy. Thus, the second data metal layer 672 may have poor resistance to chemicals and may be easily oxidized. Thus, a disconnection may easily occur and a contact resistance may be increased upon direct contact with a pixel electrode forming material, i.e., ITO, IZO, etc., and therefore the second data metal layer 672 is etched. The second data metal layer 672 can be selectively etched using a selective etching solution or gas or a time-controllable etching stopper.

Alternatively, the protection film 70 can be formed after a portion of the second data metal layer 672 corresponding to the contact hole 77 is etched.

As described above, when a photoresist film pattern is formed by reduction projection-type exposure and development of a photoresist film using the optical mask 1 according to the embodiment shown in FIG. 1 and dry etching is performed by using the photoresist film pattern as an etching mask, the contact hole 77 and the contact projection 772 are formed. In this case, the contact hole 77 and the contact projection 772 form an opening through which a portion of the first data metal layer 671 is exposed. The contact projection 772 may be formed to a narrower width and a lower height toward the inside, closer to a central area, of the contact hole 77. The contact projection 772 has a tapered angle of smaller than 90 degrees at its sidewall, with respect to a direction perpendicular to the projecting direction of the contact projection 772 in the contact hole 77, and the tapered angle of the sidewall decreases toward the interior of the contact hole 77. That is, as shown in FIGS. 2B and 2C, a tapered angle θ₂ of the sidewall of the contact projection 772 at a deeper location inside of the contact hole 77 is smaller than a tapered angle θ₁ of the sidewall of the contact projection 772 at a shallower location inside of the contact hole 77. In addition, since the height of the contact projection 772 decreases in the direction of the transparent region from the main light-shielding pattern 705, the contact projection 772 also has a tapered angle θ₃ of smaller than 90 degrees at its tip in the contact hole 77.

When a pixel electrode is deposited in the contact hole 77 and on the contact projection 772, since a sidewall of the contact projection 772 in the contact hole 77 slopes gently, the first data metal layer 671 and the pixel electrode can be electrically connected to each other in a stable manner. Therefore, a disconnection does not occur, thereby ensuring better electrical characteristics than would otherwise occur in a contact hole without the contact projection 772.

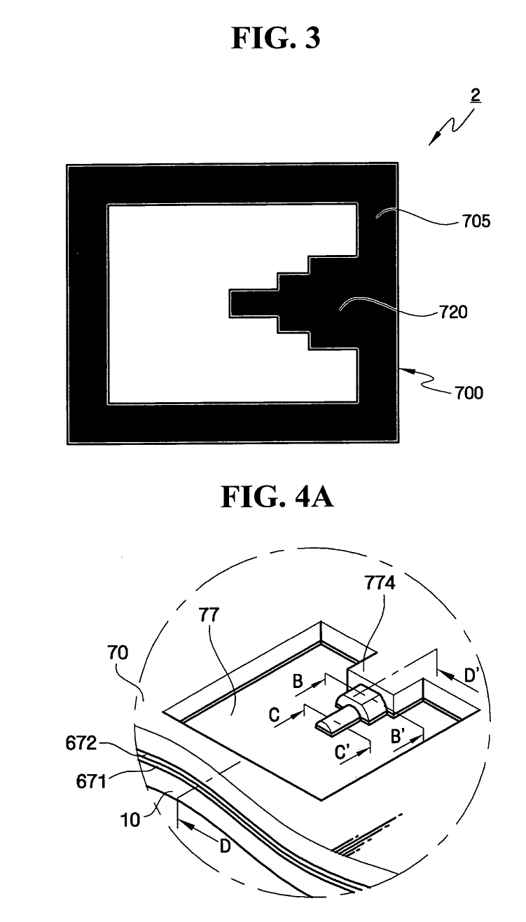

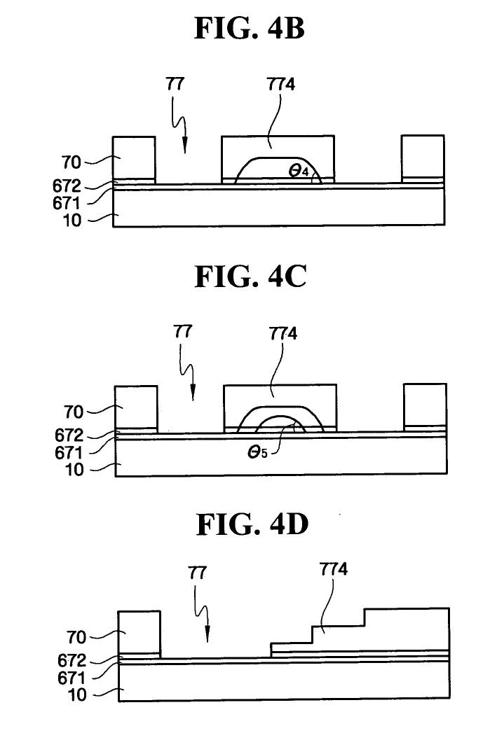

Hereinafter, an optical mask according to another exemplary embodiment of the present invention and an exemplary contact hole and an exemplary contact projection formed using the exemplary embodiment of the optical mask will be described with reference to FIGS. 3 and 4A through 4D.

First, an optical mask according to another exemplary embodiment of the present invention will be described with reference to FIG. 3. The optical mask according to the exemplary embodiment shown in FIG. 3 has substantially the same structure as the optical mask according to the exemplary embodiment shown in FIG. 1 except for those given below.

FIG. 3 is a schematic plan view of an optical mask 2 according to another exemplary embodiment of the present invention.

Referring to FIG. 3, an auxiliary light-shielding pattern 720 of the optical mask 2 has a laterally stepped structure. In this case, the auxiliary light-shielding pattern 720 may be formed so that widths of stepped regions decrease in the direction of a transparent region from a main light-shielding pattern 705. In the illustrated embodiment, the auxiliary light-shielding pattern 720 may have the shape of a plurality of abutting rectangles, where each rectangle positioned further from a side of the main light shielding pattern 705 from which the auxiliary light-shielding pattern 720 extends has a width less than a width of the rectangles positioned closer to the side of the main light-shielding pattern 705. The width of a predetermined portion of the auxiliary light-shielding pattern 720 may be smaller than a limiting resolution on an exposure machine.

An exemplary contact hole and an exemplary contact projection formed using the optical mask 2 shown in FIG. 3 will now be described with reference to FIGS. 4A through 4D. Referring to FIGS. 4A through 4D, a data metal layer composed of a first data metal layer 671 and a second data metal layer 672 is formed on a substrate 10. The first data metal layer 671 may be formed on the substrate 10, and the second data metal layer 672 may be formed on the first data metal layer 671.

FIG. 4A is a perspective view of an exemplary contact hole and an exemplary contact projection formed using the exemplary embodiment of the optical mask of FIG. 3, and FIGS. 4B through 4D are respective sectional views taken along line B-B′, line C-C′, and line D-D′ of FIG. 4A.

A protection film 70 is formed on the second data metal layer 672.

A contact hole 77 and a contact projection 774 are formed on the protection film 70. The contact hole 77 is formed on the data metal layer 671 and 672 so that a portion of the data metal layer 671 and 672 is exposed. In this case, the contact hole 77 may expose an upper surface of the first data metal layer 671, after a removal of a portion of the second data metal layer 672. The contact projection 774 is formed to project toward the contact hole 77 from the protection film 70. A portion of the second data metal layer 672, as well as a portion of the first data metal layer 671, corresponding to the contact projection 774 is not exposed. One or more contact projections may be formed. The contact hole 77 and the contact projection 774 are formed in the protection film 70 to define an opening through which the data metal layer 671 and 672 is exposed.

The contact projection 774 has a tapered angle decreasing toward the inside of the contact hole 77 at its sidewall, with respect to a direction perpendicular to a projecting direction of the contact projection 774 in the contact hole 77. That is, as shown in FIGS. 4B and 4C, a tapered angle θ₅ of the sidewall of the contact projection 774 at a deeper location inside the contact hole 77 is smaller than a tapered angle θ₄ of the sidewall of the contact projection 774 at a shallower location inside the contact hole 77. In addition, as shown in FIG. 4D, the contact projection 774 is shaped stepwise with a height decreasing toward the inside of the contact hole 77. In other words, the thickness of the distal end of the contact projection 774 is greater at a location adjacent an edge of the contact hole 77 from which the contact projection 774 extends than a thickness of the proximal end of the contact projection 774 at a location within an interior of the contact hole 77.

Since the tapered angle of the sidewall of the contact projection 774 decreases toward the inside of the contact hole 77, the contact projection 774 comes into contact with the first data metal layer 671 in a state in which it slopes gently down to the first data metal layer 671. Therefore, a pixel electrode formed on the protection film 70 can be electrically connected to the first data metal layer 671 through the contact hole 77 and the contact projection 774 in a stable manner. Consequently, a disconnection does not occur, thereby ensuring better electrical characteristics as compared to a connection between an electrode and the data metal layer 671 through a contact hole not having the contact projection 774.

The contact hole 77 and the contact projection 774 using the optical mask 2 according to the exemplary embodiment shown in FIG. 3 can be formed in substantially the same manner as the contact hole 77 and the contact projection 772 using the optical mask 1 according to the exemplary embodiment shown in FIG. 1, and thus a detailed description thereof will be omitted.

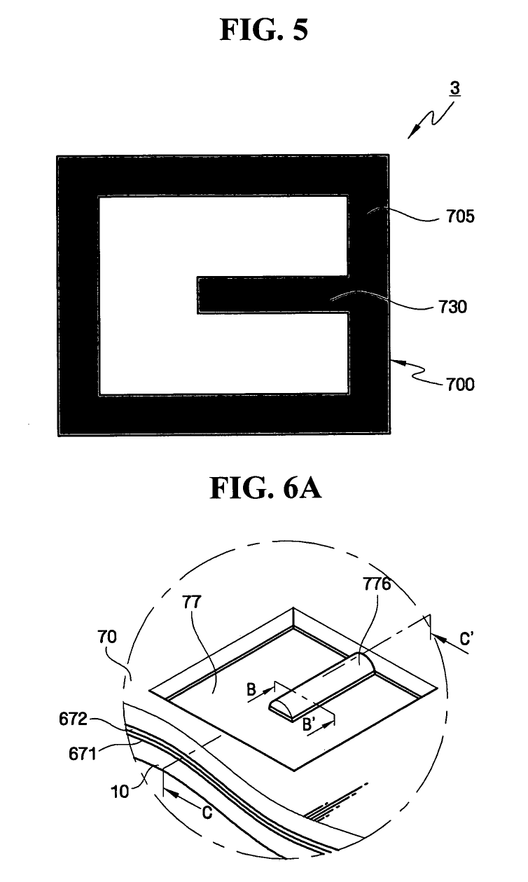

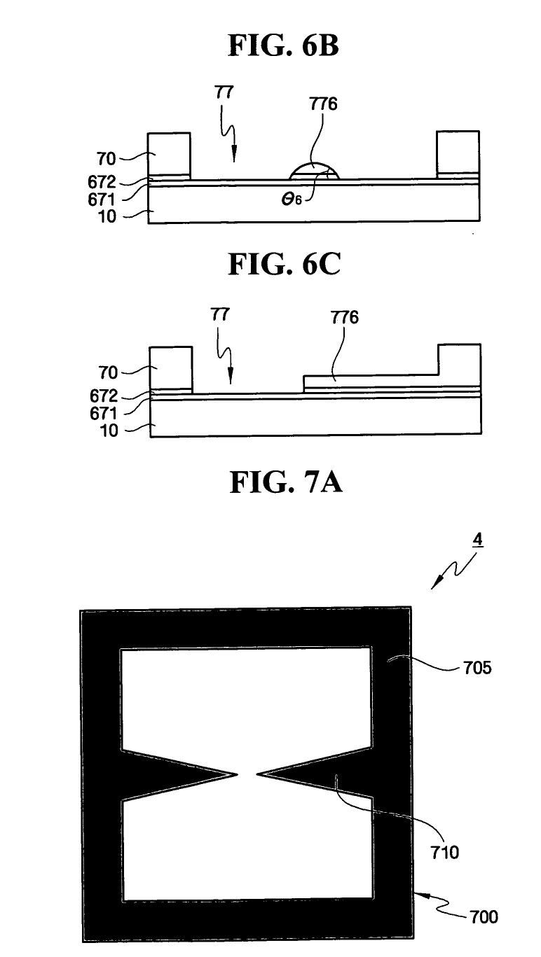

Hereinafter, an optical mask according to still another exemplary embodiment of the present invention and an exemplary contact hole and an exemplary contact projection formed using the exemplary embodiment of the optical mask will be described with reference to FIGS. 5 and 6A through 6C.

First, an optical mask according to still another exemplary embodiment of the present invention will be described with reference to FIG. 5. The optical mask according to the exemplary embodiment shown in FIG. 5 has substantially the same structure as the optical mask according to the exemplary embodiment shown in FIG. 1 except for those given below.

FIG. 5 is a schematic plan view of an optical mask 3 according to still another exemplary embodiment of the present invention.

Referring to FIG. 5, an auxiliary light-shielding pattern 730 of the optical mask 3 has a rectangular shape, as opposed to the triangular shape of the auxiliary light-shielding pattern 710 in optical mask 1 and the stepped rectangular shape of the auxiliary light-shielding pattern 720 in optical mask 2. In this case, the width of the auxiliary light-shielding pattern 730 may be smaller than a limiting resolution of an exposure machine.

An exemplary contact hole and an exemplary contact projection formed using the optical mask 3 of FIG. 5 will now be described with reference to FIGS. 6A through 6C.

FIG. 6A is a perspective view of an exemplary contact hole and an exemplary contact projection formed using the exemplary embodiment of the optical mask of FIG. 5, and FIGS. 6B and 6C are respective sectional views taken along line B-B′ and line C-C′ of FIG. 6A.

A data metal layer composed of a first data metal layer 671 and a second data metal layer 672 is formed on a substrate 10. The first data metal layer 671 may be formed on the substrate 10, and the second data metal layer 672 may be formed on the first data metal layer 671.

A protection film 70 is formed on the data metal layer. The protection film 70 is formed with a contact hole 77 and a contact projection 776. The contact hole 77 is formed on the data metal layer 671 and 672 so that a portion of the data metal layer 671 and 672 is exposed. In this case, the contact hole 77 may expose an upper surface of the first data metal layer 671, after removal of a portion of the second data metal layer 672. The contact projection 776 is formed to project toward the contact hole 77 from the protection film 70. A portion of the second data metal layer 672, as well as a portion of the first data metal layer 671, corresponding to the contact projection 776 is not exposed. One or more contact projections may be formed. The contact hole 77 and the contact projection 776 are formed in the protection film 70 to define an opening through which the data metal layer 671 and 672 is exposed.

Referring to FIG. 6A, the contact projection 776 is formed to a uniform width in the contact hole 77. In this case, a tapered angle of a sidewall of the contact projection 776 with respect to a direction extending perpendicular to a projecting direction of the contact projection 776 in the contact hole 77 may be a predetermined angle of smaller than 90 degrees. That is, as shown in FIG. 6B, the tapered angle θ₆ of the contact projection 776 is smaller than 90 degrees. The tapered angle θ₆ of the opposing sidewalls of the contact projection 776 may be uniform throughout its length.

Since the contact projection 776 has the tapered angle of smaller than 90 degrees at its sidewall in the contact hole 77, the contact projection 776 may come into contact with the first data metal layer 671 in a state in which it slopes gently down to the first data metal layer 671. Thus, a pixel electrode formed on the protection film 70 can be electrically connected to the first data metal layer 671 through the contact hole 77 and the contact projection 776 in a stable manner. Therefore, a disconnection does not occur, thereby ensuring better electrical characteristics as compared to a contact hole not having the contact projection 776.

The contact hole 77 and the contact projection 776 using the optical mask 3 according to the exemplary embodiment shown in FIG. 5 can be formed in substantially the same manner as the contact hole 77 and the contact projection 772 using the optical mask 1 according to the exemplary embodiment shown in FIG. 1, and thus a detailed description thereof will be omitted.

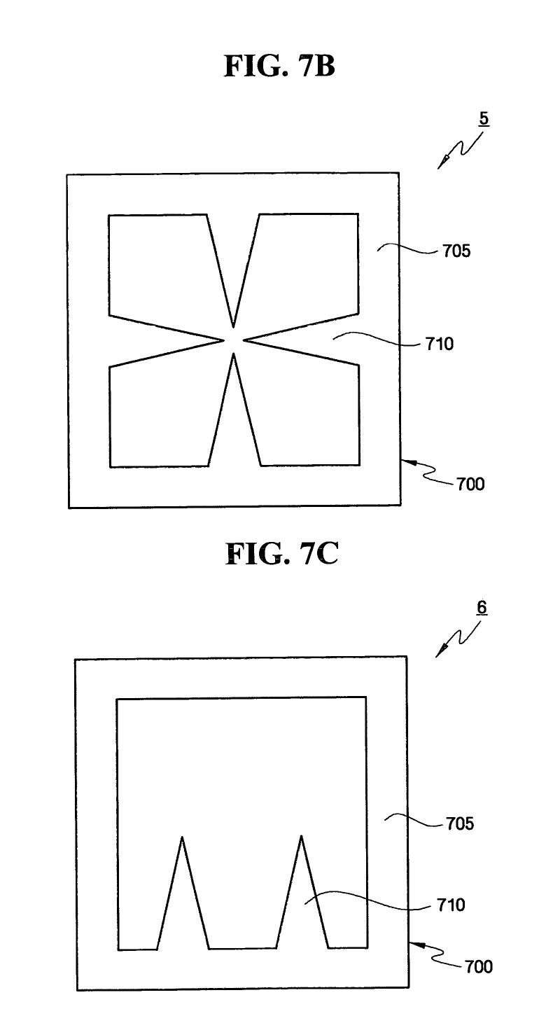

Hereinafter, optical masks according to other exemplary embodiments of the present invention and exemplary contact holes and exemplary contact projections formed using the other exemplary embodiments of the optical masks will be described with reference to FIGS. 7A through 7C.

Optical masks according to the exemplary embodiments shown in FIGS. 7A through 7C will be described. The optical masks according to the exemplary embodiments shown in FIGS. 7A through 7C have substantially the same structure as the optical mask 1 according to the exemplary embodiment shown in FIG. 1 except for those features described below.

FIGS. 7A through 7C are schematic plan views of optical masks according to other exemplary embodiments of the present invention.

Referring to FIGS. 7A through 7C, each of the optical masks 4, 5, and 6 has a plurality of auxiliary light-shielding patterns 710. In the illustrated embodiments, the optical mask 4 includes a pair of auxiliary light-shielding patterns 710 extending from opposing sides of the main light-shielding pattern 705, the optical mask 5 includes a first pair of auxiliary light-shielding patterns 710 extending from a first pair of opposing sides of the main light-shielding pattern 705 and a second pair of auxiliary light-shielding patterns 710 extending from a second pair of opposing sides of the main light-shielding pattern 705, and the optical mask 6 includes a pair of auxiliary light-shielding patterns 710 extending from a same side of the main light-shielding pattern 705. Thus, the plurality of the auxiliary light-shielding patterns 710 may face with each other or be parallel with each other in a transparent region defined by a main light-shielding pattern 705. The plurality of the auxiliary light-shielding patterns 710 may also be formed symmetrically or asymmetrically.

Each contact projection formed using one of the optical masks 4, 5, and 6 according to the exemplary embodiments shown in FIGS. 7A through 7C has the same shape as the contact projection 772 formed using the optical mask 1 according to the exemplary embodiment shown in FIG. 1, and thus, a detailed description thereof will be omitted.

Furthermore, a method of forming an exemplary contact hole and an exemplary contact projection using one of the optical masks 4, 5, and 6 according to the exemplary embodiments shown in FIGS. 7A through 7C is substantially the same as the exemplary method of manufacturing the contact hole 77 and the contact projection 772 using the optical mask 1 according to the exemplary embodiment shown in FIG. 1, and thus, a detailed description thereof will be omitted.

The structure of a contact hole and a contact projection and a method of manufacturing the same according to exemplary embodiments of the present invention can be applied to all contact-hole structures through which lower interconnection structures are exposed, in particular, to a contact-hole structure through which data wires are exposed. Furthermore, data wires are illustrated as double layers in describing a contact hole and a contact projection and a method of manufacturing the same according to exemplary embodiments of the present invention, but alternatively the data wires may have a different structure, such as a single layer or a triple layer.

Hereinafter, exemplary methods of manufacturing TFT array substrates using exemplary optical masks according to exemplary embodiments of the present invention and exemplary TFT array substrates manufactured by the exemplary methods will be described in detail so as to be easily executed by those of ordinary skill in the art.

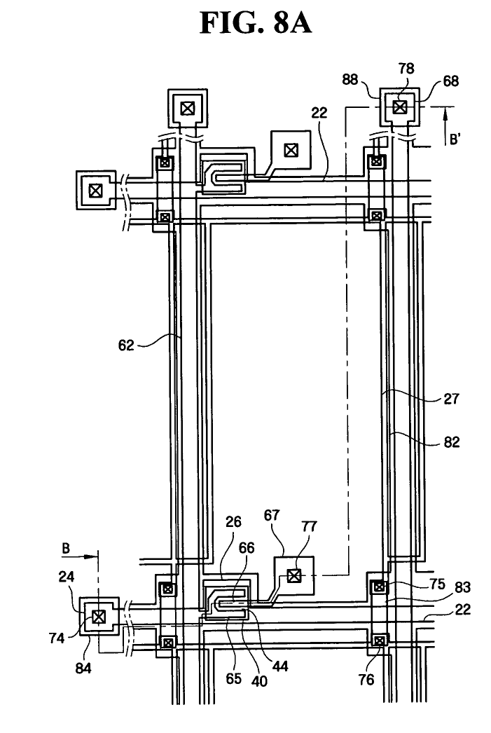

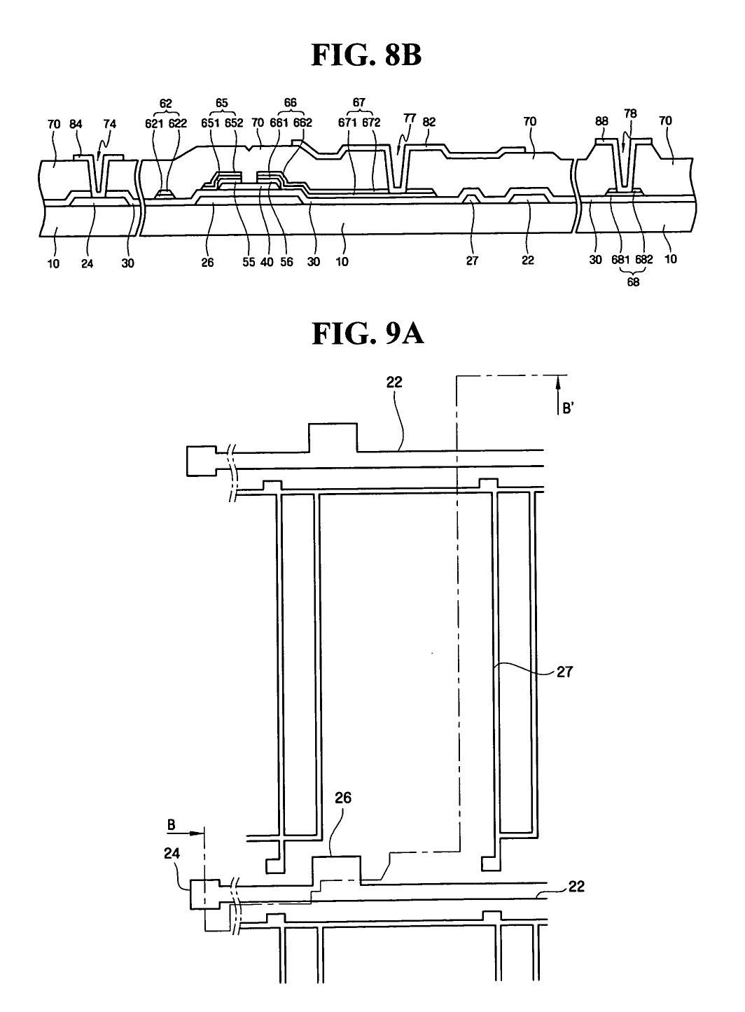

An exemplary TFT array substrate according to an exemplary embodiment of the present invention manufactured using exemplary optical masks according to exemplary embodiments of the present invention will be described with reference to FIGS. 8A and 8B.

FIG. 8A is a circuit view of an exemplary TFT array substrate according to an exemplary embodiment of the present invention, and FIG. 8B is a sectional view taken along line B-B′ of FIG. 8A.

A plurality of gate wires 22, 24, 26, and 27 for gate signal transmission are formed on an insulating substrate 10. The gate wires 22, 24, 26, and 27 include a gate line 22 extending in a row direction; a gate line terminal 24, connected to an end of the gate line 22, receiving a gate signal from the outside and transmitting the received gate signal to the gate line 22; a gate electrode 26 connected to the gate line 22 and formed to project from the gate line 22; and a sustain electrode line 27 formed in a “C”-shaped form between adjacent gate lines 22. It should be understood that the TFT array substrate includes a plurality of gate lines 22, gate line terminals 24, gate electrodes 26, and sustain electrode lines 27, however for clarity of description, one of each element will be described with respect to a pixel region of the TFT array substrate, where the TFT array substrate may include a plurality of pixel regions arranged in a matrix. Here, the gate wires 22, 24, 26, and 27 may be formed as a single layer made of aluminum (Al) or Al alloy or as a double layer composed of an Al or Al alloy layer and a molybdenum (Mo) or Mo alloy layer. The sustain electrode line 27 surrounds a pixel region in a “C”-shaped form, and thus enhances the charge storage capability of a pixel. The shape and arrangement of the sustain electrode line 27 can be changed diversely. When sustain capacity generated by overlapping between a pixel electrode 82 and the gate line 22 is sufficient, the sustain electrode line 27 may be omitted.

The substrate 10 and the gate wires 22, 24, 26, and 27 are covered with a gate insulating layer 30 made of silicon nitride (SiNx), or the like.

An island-shaped semiconductor layer 40 made of a semiconductor such as hydrogenated amorphous silicon (a —Si) or polycrystalline silicon is formed on the gate insulating layer 30 of the gate electrode 26. Ohmic contact layers 55 and 56 made of a material such as silicide or n+ hydrogenated amorphous silicon doped with high-concentration n-type impurity are formed on the semiconductor layer 40.

Data wires 62, 65, 66, 67, and 68 are formed on the ohmic contact layers 55 and 56 and the gate insulating layer 30. The data wires 62, 65, 66, 67, and 68 include a data line 62 extending in a column direction substantially perpendicular to the row direction and intersecting the gate line 22 to define pixels; a source electrode 65 connected to the data line 62 and extending over the ohmic contact layer 55; a data line terminal 68 connected to an end of the data line 62 and receiving an image signal from the outside; a drain electrode 66 separated from the source electrode 65 to be opposite to the source electrode 65 with respect to the gate electrode 26; and a drain electrode extension portion 67 extended from the drain electrode 66.

The data wires 62, 65, 66, 67, and 68 may be respectively composed of first data metal layers 621, 651, 661, 671, and 681, and second data metal layers 622, 652, 662, 672, and 682. Here, the second data metal layers 622, 652, 662, 672, and 682, which are main wire layers, may be made of metal with low resistivity to prevent signal delay due to wire resistance. For example, aluminum Al or its alloy may be used. However, aluminum Al or its alloy has poor resistance to chemicals and is easily oxidized. Thus, a disconnection may easily occur and a contact resistance may be increased upon direct contact with a pixel electrode forming material, such as ITO or IZO. In view of these problems, the first data metal layers 621, 651, 661, 671, and 681 may be made of metal with good resistance to chemicals and good contact resistance with the pixel electrode 82. For example, chromium (Cr), molybdenum (Mo), titanium (Ti), or the like may be used for the first data metal layers 621, 651, 661, 671, and 681.

The source electrode 65 overlaps with at least a portion of the semiconductor layer 40. The drain electrode 66 is opposed to the source electrode 65 with respect to the gate electrode 26 and overlaps with at least a portion of the semiconductor layer 40. The ohmic contact layers 55 and 56 are interposed between the underlying semiconductor layer 40 and the overlying source and drain electrodes 65 and 66 to reduce a contact resistance. The source and drain electrodes 65, 66 are spaced from each other to define a channel there between.

A protection film 70 is formed on the data wires 62, 65, 66, 67, and 68, and an exposed portion of the semiconductor layer 40. The protection film 70 may further be formed on any exposed portions of the gate insulating layer 30. The protection film 70 may be made of an organic material having excellent planarization characteristics and photosensitivity, a low-dielectric insulating material such as a-Si:C:O or a-Si:O:F deposited by PECVD, or an inorganic material such as silicon nitride (SiNx). When the protection film 70 is made of an organic material, an insulating film (not shown) made of silicon nitride (SiNx) or silicon oxide (SiO₂) may further be formed on the lower surface of the protection film 70 to prevent the organic material of the protection film 70 from contacting with an exposed portion of the semiconductor layer 40 between the source electrode 65 and the drain electrode 66.

Contact holes 77 and 78 are formed in the protection film 70 to expose the drain electrode extension portion 67 and the data line terminal 68, respectively. Also, the protection film 70 and the gate insulating layer 30 are formed with a contact hole 74 exposing the gate line terminal 24 and a contact hole 75 (and contact hole 76 on an adjacent pixel) exposing the sustain electrode line 27.

Here, one or more contact projections (for example, 772 of FIG. 2A, 774 of FIG. 4A, and 776 of FIG. 6A) are formed in the contact hole 78 exposing the data line terminal 68 and the contact hole 77 exposing the drain electrode extension portion 67.

Here, the contact projections may be the same as any of the contact projections 772, 774, and 776, or alternative embodiments thereof, formed using the optical masks according to preferred embodiments of the present invention.

The pixel electrode 82 is formed on the protection film 70 in such a way to be electrically connected to the drain electrode 66 through the contact hole 77 and the contact projection (for example, 772 of FIG. 2A, 774 of FIG. 4A, or 776 of FIG. 6A) and to be positioned in a pixel region. When a data voltage is applied to the pixel electrode 82, the pixel electrode 82, together with a common electrode of an upper substrate, generates an electric field. The generated electric field determines the orientation of liquid crystal molecules within a liquid crystal layer between the pixel electrode 82 and the common electrode.

An auxiliary gate line terminal 84 and an auxiliary data line terminal 88 are also formed on the protection film 70 in such a way so as to be connected to the gate line terminal 24 and the data line terminal 68 through the contact holes 74 and 78, respectively. Here, the pixel electrode 82 and the auxiliary gate and data line terminals 86 and 88 may be made of, but are not limited to, ITO.

A sustain electrode line connection bridge 83 is also formed on the protection film 70 to connect the sustain electrode line 27 formed at one unit pixel and the sustain electrode line 27 formed at an adjacent unit pixel. The sustain electrode line connection bridge 83 comes into contact with the sustain electrode lines 27 through the contact holes 75 and 76 formed in the protection film 70 and the gate insulating layer 30. The sustain electrode line connection bridges 83 electrically connect all sustain electrode lines 27 formed on the substrate 10. The sustain electrode line connection bridge 83 does not overlap with the pixel electrode 82, and a higher voltage than an average voltage of the pixel electrode 82 is applied thereto. Thus, the sustain electrode line connection bridge 83 also serves as a gathering electrode collecting negative (−) ion impurities.

Hereinafter, an exemplary method of manufacturing an exemplary TFT array substrate according to an exemplary embodiment of the present invention using exemplary optical masks according to exemplary embodiments of the present invention will be described in detail with reference to FIGS. 8A and 8B, and 9A through 13.

First, with reference to FIGS. 9A and 9B, a metal film (not shown) for gate wires is deposited on a substrate 10 and patterned to form gate wires 22, 24, 26, and 27 including a gate line 22, a gate line terminal 24, a gate electrode 26, and a sustain electrode line 27. Here, the gate wires 22, 24, 26, and 27 may be formed, for example, as a single layer made of Al or Al alloy (e.g., AlNd) or as a double layer composed of an Al or Al alloy (e.g., AlNd) layer and a Mo or Mo alloy layer deposited on the Al or Al alloy layer.

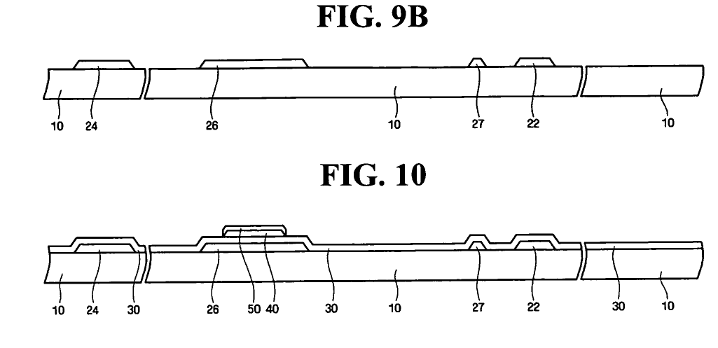

Next, as shown in FIG. 10, a gate insulating layer 30 made of silicon nitride, an intrinsic amorphous silicon a —Si layer (not shown), and a doped amorphous silicon a —Si layer (not shown) may be continuously deposited to a thickness of 1,500-5,000□, 500-2,000□, and 300-600□, respectively, by a chemical vapor deposition method. The intrinsic amorphous silicon a-Si layer (not shown) and the doped amorphous silicon a-Si layer (not shown) are etched by photolithography to form an island-shaped semiconductor layer 40 and a doped amorphous silicon a-Si pattern 50 on a portion of the gate insulating layer 30 corresponding to the gate electrode 26.

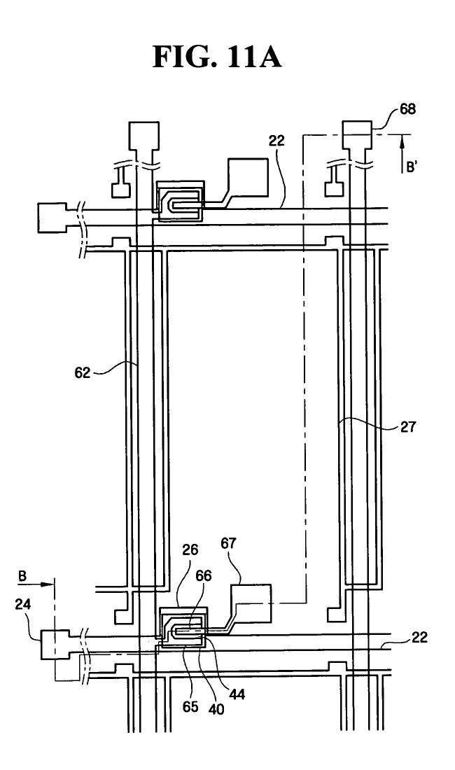

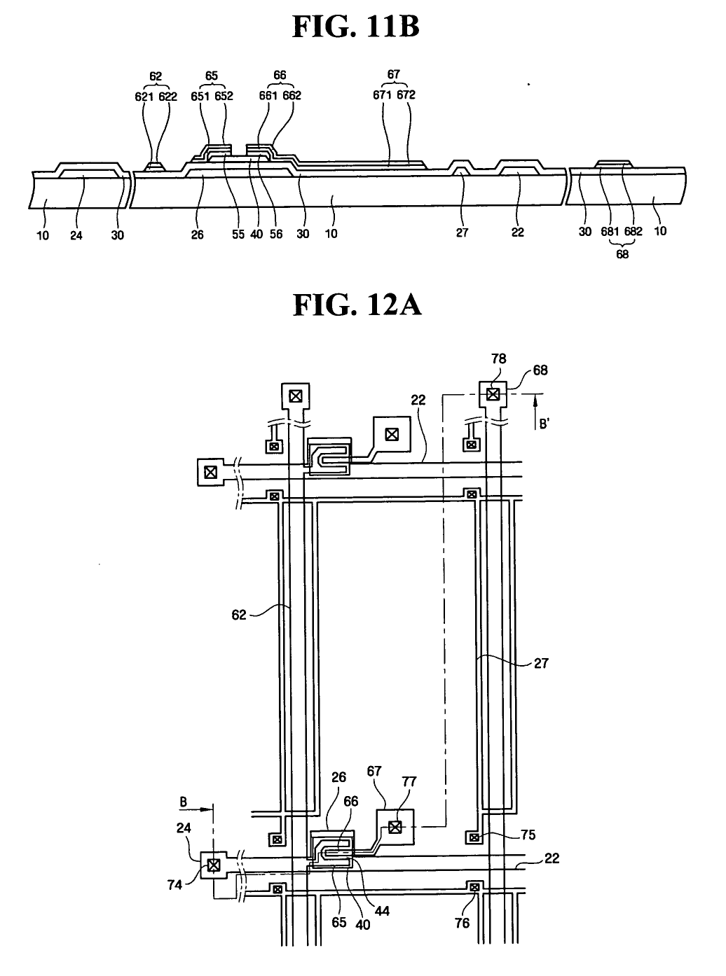

Next, as shown in FIGS. 11A and 11B, the first data metal layers 621, 651, 661, 671, and 681 and second data metal layers 622, 652, 662, 672, and 682 are sequentially formed. Here, the first data metal layers 621, 651, 661, 671, and 681 may be made of chromium, molybdenum, titanium, or a compound thereof, and the second data metal layers 622, 652, 662, 672, and 682 may be made of aluminum or its alloy.

The first data metal layers 621, 651, 661, 671, and 681 and the second data metal layers 622, 652, 662, 672, and 682 may be formed by sputtering or evaporation deposition.

Then, the first data metal layers 621, 651, 661, 671, and 681 and the second data metal layers 622, 652, 662, 672, and 682 are etched by photolithography to thereby form data wires 62, 65, 66, 67, and 68 including a data line 62 intersecting the gate line 22; a source electrode 65 connected to the data line 62 and extending over the gate electrode 26; a data line terminal 68 connected to an end of the data line 62; a drain electrode 66 separated from the source electrode 65 to be opposite to the source electrode 65 with respect to the gate electrode 26; and a drain electrode extension portion 67 extended from the drain electrode 66.

Next, a portion of the doped amorphous silicon a-Si layer exposed by the data wires 62, 65, 66, 67, and 68 is etched to separate the source and drain electrodes 65 and 66 and ohmic contact layers 55 and 56 with respect to the gate electrode 26. At the same time, the semiconductor layer 40 between the ohmic contact layers 55 and 56 is exposed, thus forming a channel between the source electrode 65 and drain electrode 66. In this case, to stabilize the exposed surface of the semiconductor layer 40, oxygen plasma may be performed.

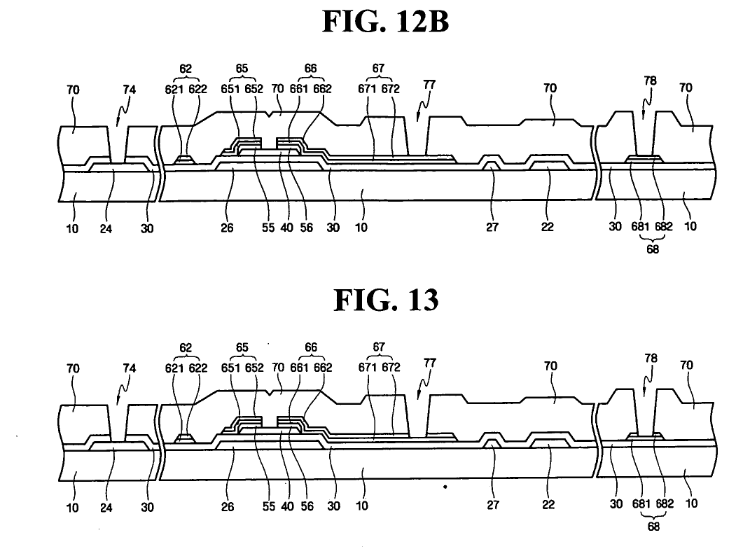

Next, as shown in FIGS. 12A and 12B, a protection film 70 is formed on the second data metal layers 622, 652, 662, 672, and 682. For example, the protection film 70 may be made of an organic material with good planarization characteristics and photosensitivity, a low-dielectric insulating material such as a-Si:C:O or a-Si:O:F formed by PECVD, or an inorganic material such as silicon nitride (SiNx).

Then, the protection film 70, together with the gate insulating layer 30, are etched by photolithography to form contact holes 77, 74, 78, and 75 (and contact hole 76 in an adjacent pixel) exposing the drain electrode extension portion 67, the gate line terminal 24, the data line terminal 68, and the sustain electrode line 27, respectively. In this case, one or more contact projections (for example, 772 of FIG. 2A, 774 of FIG. 4A, and 776 of FIG. 6A) are formed in the contact hole 78 exposing the data line terminal 68 and the contact hole 77 exposing the drain electrode extension portion 67.

Here, the contact holes 77 and 78 and the contact projections 772, 774, and 776 are formed in the same method as described above in the exemplary methods of forming exemplary contact holes and exemplary contact projections using exemplary optical masks according to exemplary embodiments of the present invention. Since a sidewall of the contact projection 772, 774, or 776 slopes gently with respect to a direction extending perpendicular to a projecting direction of the contact projection 772, 774, or 776, the drain electrode extension portion 67 and the data line terminal 68 can be electrically connected to the pixel electrode 82 and the auxiliary data line terminal 88, respectively, in a stable manner. Therefore, a disconnection does not occur, thereby ensuring better electrical characteristics as compared to electrical characteristics in a TFT array substrate not having at least one of the contact projections 772, 774, or 776 in each of the contact holes 77 and 78.

Next, as shown in FIG. 13, portions of the second data metal layers 672 and 682 exposed through the contact holes 77 and 78 are etched. The second data metal layers 672 and 682 are made of aluminum Al or its alloy, and thus have poor resistance to chemicals and are easily oxidized. Thus, a disconnection is easily caused and a contact resistance is increased upon direct contact with a pixel electrode forming material such as, but not limited to, ITO or IZO, and therefore the second data metal layers 672 and 682 are etched such that the pixel electrode forming material can come into contact with the first data metal layers 671 and 681 instead. The second data metal layers 672 and 682 can be selectively etched using a selective etching solution or gas or a time-controllable etching stopper.

Next, finally, referring back to FIGS. 8A and 8B, an ITO film (not shown) or the like is deposited and etched by photolithography to thereby form the pixel electrode 82 connected to the drain electrode 66 through the contact hole 77 in the drain electrode extension portion 67, and the auxiliary gate line terminal 84 and the auxiliary data line terminal 88 respectively connected to the gate line terminal 24 and the data line terminal 68 through the contact holes 74 and 78. At the same time, the sustain electrode line connection bridge 83 connecting the sustain electrode lines 27 through the contact holes 75 and 76 is formed.

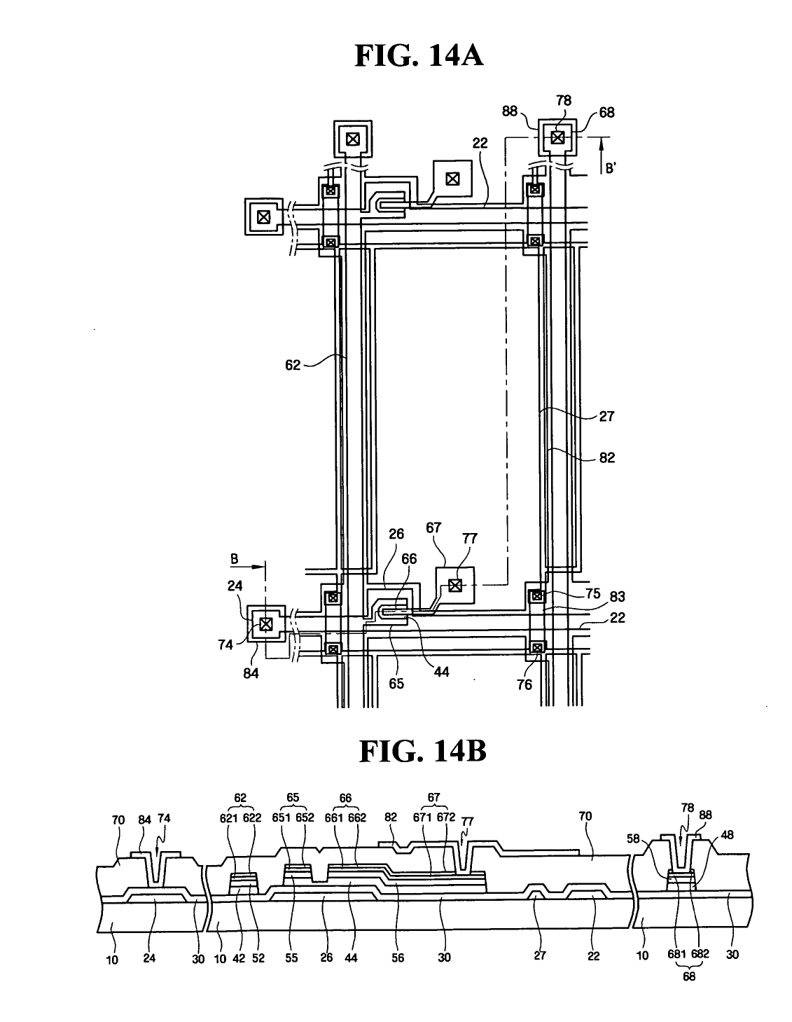

Hereinafter, an exemplary TFT array substrate according to another exemplary embodiment of the present invention manufactured using exemplary optical masks according to exemplary embodiments of the present invention will be described with reference to FIGS. 14A and 14B.

FIG. 14A is a circuit view of an exemplary TFT array substrate according to another exemplary embodiment of the present invention, and FIG. 14B is a sectional view taken along line B-B′ of FIG. 14A.

As in the exemplary embodiment shown in FIGS. 8A and 8B, a plurality of gate wires 22, 24, 26, and 27 for gate signal transmission are first formed on an insulating substrate 10. The gate wires 22, 24, 26, and 27 include a gate line 22 extending in a row direction; a gate line terminal 24, connected to an end of the gate line 22, receiving a gate signal from an exterior source and transmitting the received gate signal to the gate line 22; a gate electrode 26 connected to the gate line 22 and formed to project from the gate line 22; and a sustain electrode line 27 formed in a “C”-shaped and formed between adjacent gate lines 22. Here, the gate wires 22, 24, 26, and 27 may be formed as a single layer made of aluminum (Al) or Al alloy or as a double layer composed of an Al or Al alloy layer and a molybdenum (Mo) or Mo alloy layer. The sustain electrode line 27 surrounds a pixel region in a “C”-shaped form, and thus enhances the charge storage capability of a pixel. The shape and arrangement of the sustain electrode line 27 can be changed diversely. When sustain capacity generated by overlapping between a pixel electrode 82 and the gate line 22 is sufficient, the sustain electrode line 27 may be omitted.

A gate insulating layer 30 made of silicon nitride (SiNx), or the like is formed on the substrate 10 and the gate wires 22, 24, 26, and 27.

Semiconductor patterns 42, 44, and 48 made of a semiconductor such as hydrogenated amorphous silicon a-Si or polycrystalline silicon are formed on the gate insulating layer 30.

Ohmic contact layers 52, 55, 56, and 58 made of n+ hydrogenated amorphous silicon a-Si doped with high-concentration n-type impurity (e.g., silicide) or the like are formed on the semiconductor patterns 42, 44, and 48. Data wires 62, 65, 66, 67, and 68 are formed on the ohmic contact layers 52, 55, 56, and 58, respectively.

The data wires 62, 65, 66, 67, and 68 include a data line 62 extending in a column direction substantially perpendicular to the row direction and intersecting the gate line 22 to define pixels; a source electrode 65, which is a branch of the data line 62, extending over the ohmic contact layer 55; a data line terminal 68 connected to an end of the data line 62 and receiving an image signal from the outside; a drain electrode 66 separated from the source electrode 65 to be opposite to the source electrode 65 with respect to the gate electrode 26; and a drain electrode extension portion 67 extended from the drain electrode 66.

The data wires 62, 65, 66, 67, and 68 may be respectively composed of first data metal layers 621, 651, 661, 671, and 681, and second data metal layers 622, 652, 662, 672, and 682. Here, the second data metal layers 622, 652, 662, 672, and 682, which are main wire layers, may be made of metal with low resistivity to prevent signal delay due to wire resistance. For example, aluminum Al or its alloy may be used. However, aluminum Al or its alloy has poor resistance to chemicals and is easily oxidized. Thus, a disconnection may easily occur and a contact resistance may be increased upon direct contact with a pixel electrode forming material, such as ITO or IZO. In view of these problems, the first data metal layers 621, 651, 661, 671, and 681 may be made of metal with good resistance to chemicals and good contact resistance with the pixel electrode 82. For example, chromium (Cr), molybdenum (Mo), titanium (Ti), or the like may be used.

The source electrode 65 overlaps with at least a portion of the semiconductor pattern 44. The drain electrode 66 is opposing to the source electrode 65 with respect to the gate electrode 26 and overlaps with at least a portion of the semiconductor pattern 44. The ohmic contact layers 55 and 56 are interposed between the underlying semiconductor pattern 44 and the overlying source and drain electrodes 65 and 66 to reduce a contact resistance.

The ohmic contact layers 52, 55, 56, and 58 serve to reduce a contact resistance between the underlying semiconductor patterns 42, 44, and 48, and the overlying data wires 62, 65, 66, 67, and 68, and have substantially the same shapes as the data wires 62, 65, 66, 67, and 68.

Meanwhile, the semiconductor patterns 42, 44, and 48 except a channel portion of a TFT have substantially the same shapes as the data wires 62, 65, 66, 67, and 68, and the ohmic contact layers 52, 55, 56, and 58. That is, the source electrode 65 and the drain electrode 66 are separated with respect to the channel portion of the TFT. The underlying ohmic contact layer 55 of the source electrode 65 and the underlying ohmic contact layer 56 of the drain electrode 66 are also separated. However, the semiconductor pattern 44 for the TFT forms the channel of the TFT without disconnection.

A protection film 70 is formed on the data wires 62, 65, 66, 67, and 68, and on a portion of the semiconductor pattern 44 exposed by the source and drain electrodes 65 and 66, that is, the channel portion. The protection film 70 may also be formed on exposed portions of the gate insulating layer 30. The protection film 70 may be made of an organic material having excellent planarization characteristics and photosensitivity, a low-dielectric insulating material such as a-Si:C:O or a-Si:O:F deposited by PECVD, or an inorganic material such as silicon nitride (SiNx). When the protection film 70 is made of an organic material, an insulating film (not shown) made of silicon nitride (SiNx) or silicon oxide (SiO₂) may further be formed on the lower surface of the protection film 70 to prevent the organic material of the protection film 70 from contacting with an exposed portion of the semiconductor pattern 44 between the source electrode 65 and the drain electrode 66 within the channel portion.

The protection film 70 is formed with contact holes 77 and 78 exposing the drain electrode extension portion 67 and the data line terminal 68, respectively. The protection film 70 and the gate insulating layer 30 are formed with a contact hole 74 exposing the gate line terminal 24 and a contact hole 75 (and contact hole 76 in an adjacent pixel region) exposing the sustain electrode line 27.

Here, one or more contact projections (for example, 772 of FIG. 2A, 774 of FIG. 4A, and 776 of FIG. 6A) are formed in the contact hole 78 exposing the data line terminal 68 and the contact hole 77 exposing the drain electrode extension portion 67.

Here, the contact projections 772, 774, and 776 are substantially the same as each of the contact projections 772, 774, and 776 formed using any one of the exemplary optical masks according to exemplary embodiments of the present invention.

A pixel electrode 82 electrically connected to the drain electrode 66 through the contact hole 77 in the drain electrode extension portion 67 and one or more of the contact projection 772, 774, or 776 is formed on the protection film 70. When a data voltage is applied to the pixel electrode 82 via the drain electrode 66, the pixel electrode 82, together with a common electrode of an upper substrate, generates an electric field. The generated electric field determines the orientation of liquid crystal molecules within a liquid crystal layer between the pixel electrode 82 and the common electrode.

An auxiliary gate line terminal 84 and an auxiliary data line terminal 88 respectively connected to the gate line terminal 24 and the data line terminal 68 through the contact holes 74 and 78 are also formed on the protection film 70. The pixel electrode 82 and the auxiliary gate and data line terminals 86 and 88 may be made of ITO or the like.

A sustain electrode line connection bridge 83 connecting sustain electrode lines 27 in adjacent pixel regions is also formed on the protection film 70. The sustain electrode line connection bridge 83 comes into contact with the sustain electrode lines 27 through the contact holes 75 and 76 formed on the protection film 70 and the gate insulating layer 30. The sustain electrode line connection bridges 83 electrically connect all sustain electrode lines 27 formed on the substrate 10. The sustain electrode line connection bridge 83 does not overlap with the pixel electrode 82, and a higher voltage than an average voltage of the pixel electrode 82 is applied thereto. Thus, the sustain electrode line connection bridge 83 also serves as a gathering electrode collecting negative (−) ion impurities.

Hereinafter, an exemplary method of manufacturing a TFT array substrate according to another exemplary embodiment of the present invention using exemplary optical masks according to exemplary embodiments of the present invention will be described with reference to FIGS. 14A and 14B and 15A through 24.

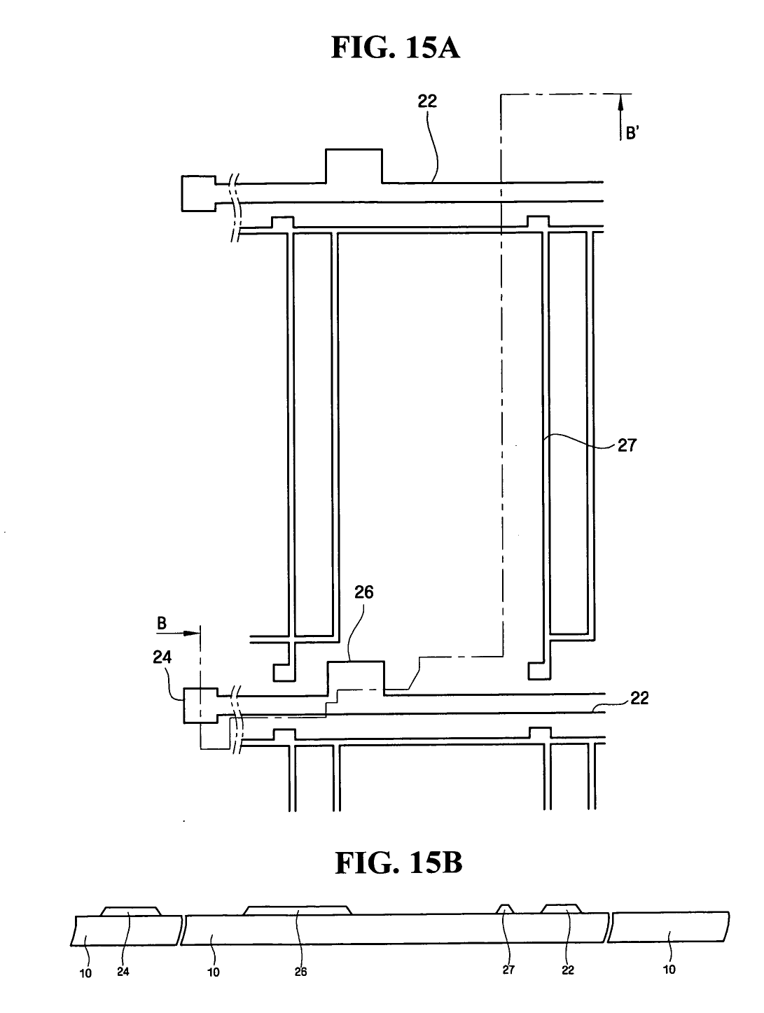

First, as shown in FIGS. 15A and 15B, a multi-layer metal film (not shown) for gate wires is deposited on a substrate 10 and patterned to form gate wires 22, 24, 26, and 27 including a gate line 22, a gate line terminal 24, a gate electrode 26, and a sustain electrode line 27. Here, the gate wires 22, 24, 26, and 27 may be formed as a single layer made of Al or Al alloy (e.g., AlNd) or as a double layer composed of an Al or Al alloy (e.g., AlNd) layer and a Mo or Mo alloy layer deposited on the Al or Al alloy layer.

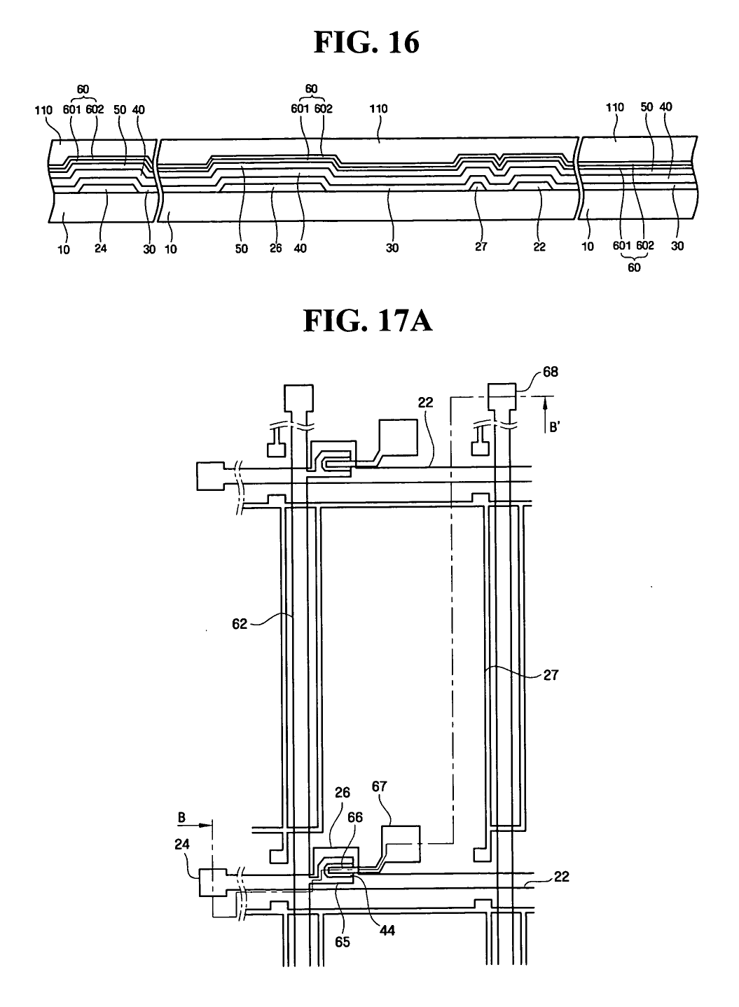

Next, as shown in FIG. 16, a gate insulating layer 30 made of silicon nitride, an intrinsic amorphous silicon a-Si layer 40, and a doped amorphous silicon a-Si layer 50 may be continuously deposited to a thickness of 1,500-5,000□, 500-2,000□, and 300-600□, respectively, by a chemical vapor deposition method. Then, a first data metal film 601 for first data metal layers (621, 651, 661, 671, and 681 of FIG. 14B) and a second data metal film 602 for second data metal layers (622, 652, 662, 672, and 682 of FIG. 14B) are sequentially deposited on the doped amorphous silicon a-Si layer 50 by sputtering, or the like, to form a data metal film 60. Here, the first data metal film 601 may be made of, but not limited to, chromium, molybdenum, titanium, or a compound thereof, and the second data metal film 602 may be made of, for example, aluminum or its alloy.

Then, a photoresist film 110 is coated on the data metal film 60.

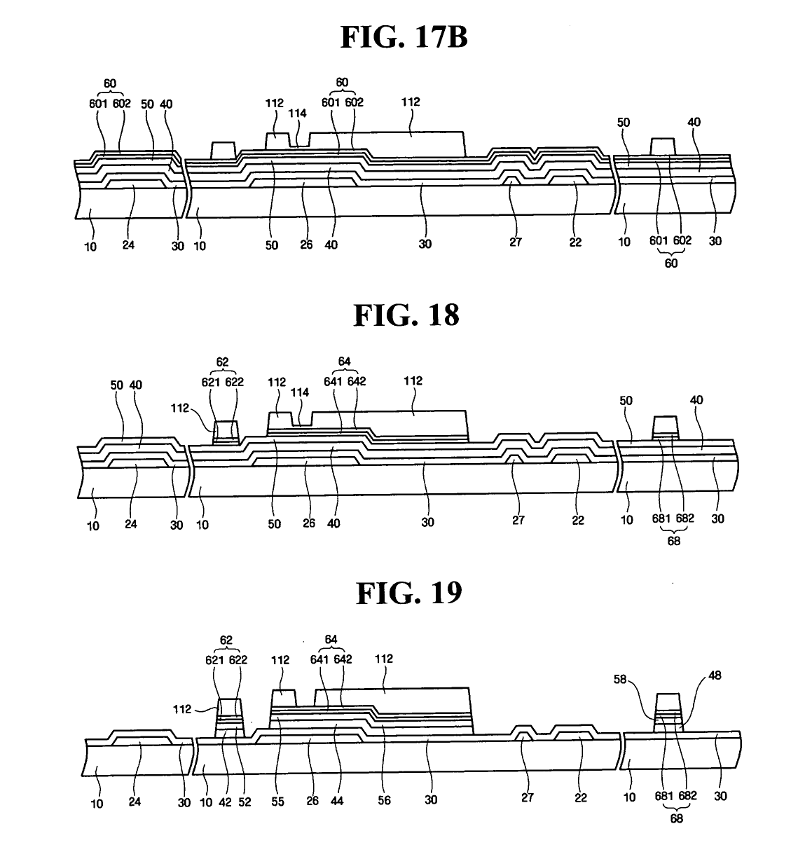

Next, referring to FIGS. 17A and 17B, the photoresist film 110 is exposed to light through a mask and developed to form photoresist film patterns 112 and 114. In this case, a first photoresist film pattern 114 corresponding to a channel portion of a TFT, i.e., a region between a source electrode 65 and a drain electrode 66 is formed to a thinner thickness than a second photoresist film pattern 112 corresponding to data wires 62, 65, 66, 67, and 68. The photoresist film portions except the photoresist film patterns 112 and 114 corresponding to the channel portion and the data wires are removed. In this case, a thickness ratio of the first photoresist film pattern 114 remaining on the channel portion to the second photoresist film pattern 112 remaining on the data wires is changed according to the conditions of an etching process as will be described below. Preferably, the thickness of the first photoresist film pattern 114 is ½ or less of the thickness of the second photoresist film pattern 112. For example, the thickness of the first photoresist film pattern 114 may be 4,000 Å or less.

The thicknesses of the photoresist film patterns 112 and 114 can be changed by various methods. For example, to adjust light transmittance of the first photoresist film pattern 114, a slit or lattice type pattern or a translucent film may be used.

When using a slit or lattice type pattern, it is preferable to adjust a linewidth of a pattern between adjacent slits or a distance between adjacent patterns, i.e., a width of a slit, to be smaller than the resolution of an exposure machine.

In the case of using a translucent film, to adjust light transmittance in fabrication of masks, thin films with different transmittances or thicknesses may be used. When a photoresist film is exposed to light through such masks, polymers of an exposed region of the photoresist film are completely decomposed.

However, with respect to a portion of photoresist film corresponding to a slit pattern or a translucent film, less light is transmitted there through and thus polymers are not completely decomposed. Polymers in a portion of the photoresist film blocked by a light-shielding film are not decomposed much. When the photoresist film thus exposed is developed, a portion of the photoresist film where polymers are not decomposed remains. A center portion of the photoresist film exposed to less light is left thinner than an unexposed portion of the photoresist film. In this case, when the photoresist film is exposed for a longer time, all polymers can be decomposed. Thus, it is preferable to appropriately adjust an exposure time.

Alternatively, the first photoresist film pattern 114 with a thinner thickness can also be obtained by using the photoresist film 110, as shown in FIG. 16, made of a reflowable material. In this case, the photoresist film 110 is exposed to light through a common mask having a transparent portion and an opaque portion, followed by developing and reflowing so that a portion of the photoresist film 110 flows to the portion where the photoresist film 110 does not remain.

Then, the first photoresist film pattern 114 and the underlying first data metal film 601 and second data metal film 602 are etched.

Consequently, as shown in FIG. 18, portions of the first and second data metal films 601 and 602, except for a channel portion and except for data metal film patterns 62, 64, and 68, are removed so that the doped amorphous silicon a-Si layer 50 is exposed. In this case, the remaining metal film patterns 62, 64, and 68 have substantially the same shapes as the resultant data wires 62, 65, 66, 67, and 68 except that the source and drain electrodes 65 and 66 are not separated.

Next, as shown in FIG. 19, an exposed portion of the doped amorphous silicon a-Si layer 50 and the underlying intrinsic amorphous silicon a-Si layer 40 are removed by dry etching, together with the first photoresist film pattern 114. In this case, the first and second photoresist film patterns 114 and 112, the exposed portion of the doped amorphous silicon a-Si layer 50, and the underlying intrinsic amorphous silicon a-Si layer 40 are etched at the same time under the condition that the gate insulating layer 30 is not etched. In particular, it is preferable that the first and second photoresist film patterns 114 and 112 and the intrinsic amorphous silicon a-Si layer 40 are etched at almost the same etch rate. For example, the first and second photoresist film patterns 114 and 112 and the intrinsic amorphous silicon a-Si layer 40 can be etched to almost the same thickness using a mixed gas of SF₆ and HCl or O₂. When an etch rate of the first and second photoresist film patterns 114 and 112 is the same as that of the intrinsic amorphous silicon a-Si layer 40, the thickness of the first photoresist film pattern 114 must be equal to or smaller than the sum of the thickness of the intrinsic amorphous silicon a-Si layer 40 and the doped amorphous silicon a-Si layer 50. Consequently, as shown in FIG. 19, the metal film pattern 64 for source/drain is exposed within the channel region by removal of the first photoresist film pattern 114 and the gate insulating layer 30 is exposed in areas not covered by a metal film pattern by removal of the exposed portion of the doped amorphous silicon a-Si layer 50 and the underlying intrinsic amorphous silicon a-Si layer 40. In this case, the second photoresist film pattern 112 on the data wires is also etched to a thinner thickness.

Then, a photoresist film residue on a surface of the metal film pattern 64 for source/drain corresponding to a channel portion is removed by ashing.

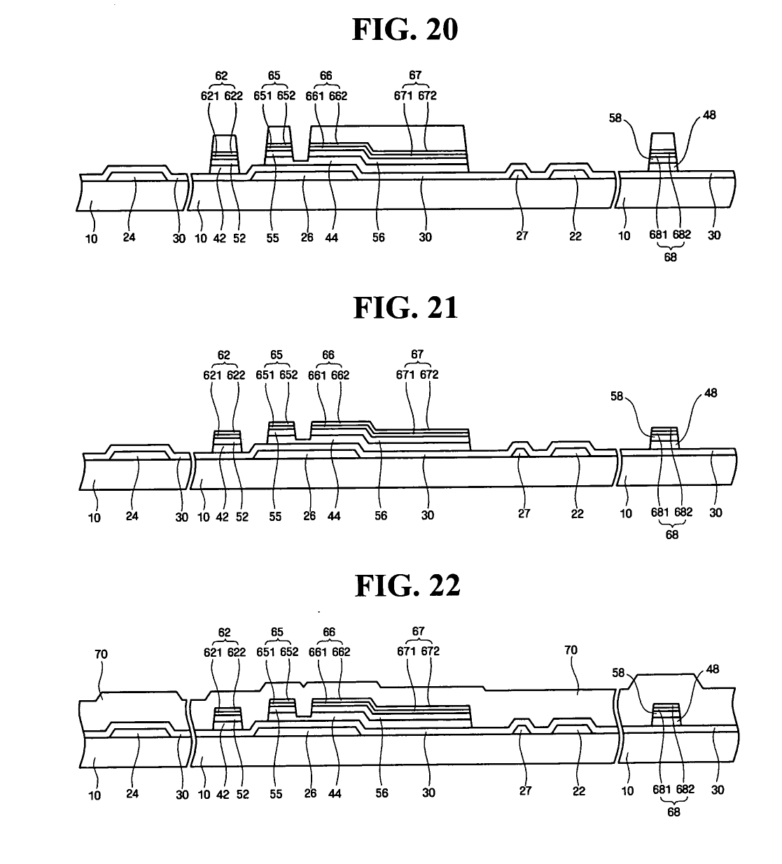

Next, as shown in FIG. 20, the metal film pattern 64 is etched for removal in an area corresponding to the channel portion such that the first data metal layers 621, 651, 661, 671, and 681 and the second data metal layers 622, 652, 662, 672, and 682 remain.

Then, the doped amorphous silicon a-Si layer 50 for ohmic contact layers 55 and 56 is etched. In this case, dry etching may be used using an etching gas such as a mixed gas of CF₄ and HCl or O₂. When a mixed gas of CF₄ and O₂ is used, a semiconductor pattern 44 made of intrinsic amorphous silicon a-Si can be formed to a uniform thickness. In this case, the semiconductor pattern 44 may have a smaller thickness by partial removal and the second photoresist film pattern 112 may also be etched to a thinner thickness. In this case, the etching must be performed under the condition that the gate insulating layer 30 is not etched. Of course, it is preferable that the second photoresist film pattern 112 has such a sufficient thickness that underlying data wires 62, 65, 66, 67, and 68 are not exposed during etching.

Thus, the source electrode 65, the drain electrode 66, and the ohmic contact layers 55 and 56 are completed.

Next, as shown in FIG. 21, the second photoresist film pattern 112 is removed. Then, as shown in FIG. 22, a protection film 70 is formed.

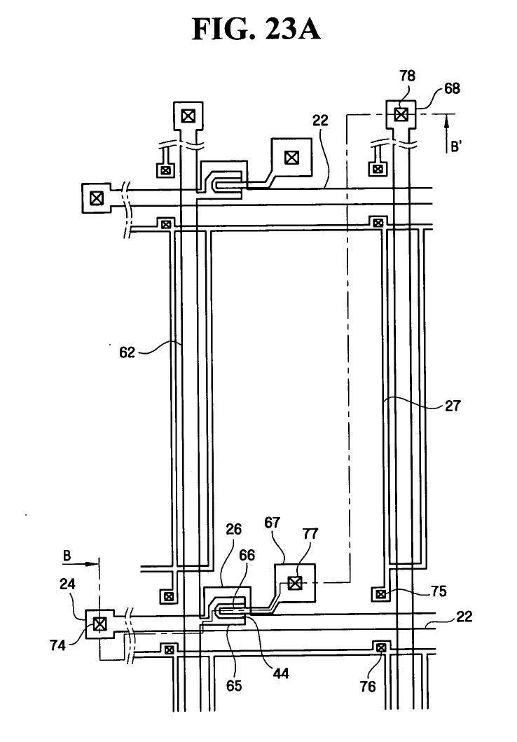

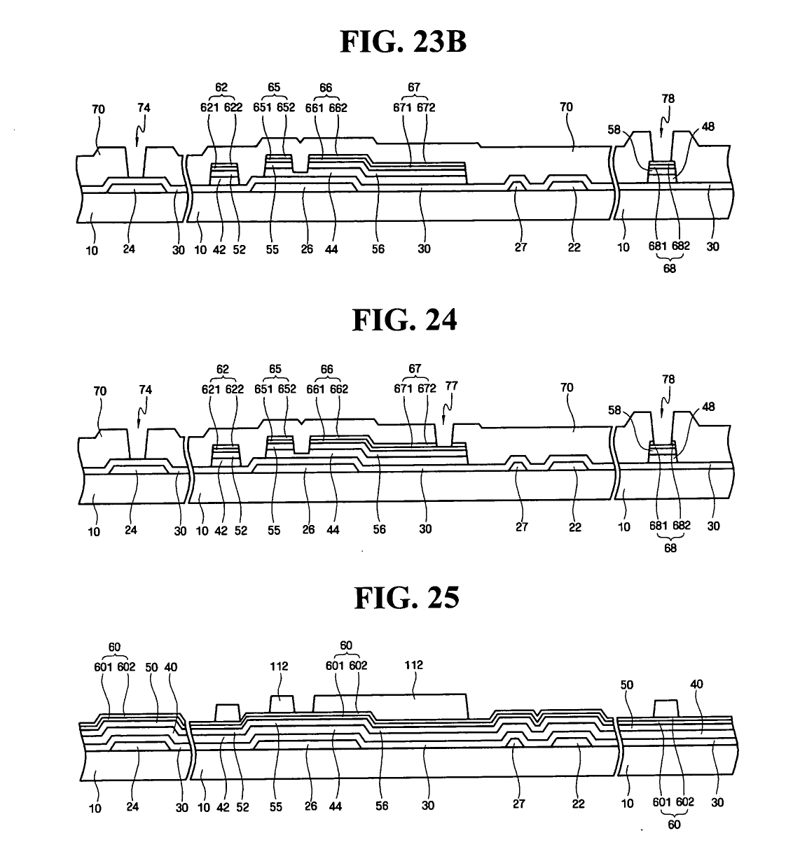

Next, as shown in FIGS. 23A and 23B, the protection film 70, together with the gate insulating layer 30, is etched by photolithography to form contact holes 77, 74, 78, and 75 (and contact hole 76 in adjacent pixel region) through which the drain electrode extension portion 67, the gate line terminal 24, the data line terminal 68, and the sustain electrode line 27, respectively, are exposed. In this case, one or more contact projections (for example, 772 of FIG. 2A, 774 of FIG. 4A, and 776 of FIG. 6A) are formed in the contact hole 78 exposing the data line terminal 68 and the contact hole 77 exposing the drain electrode extension portion 67.

Here, the formation of the contact holes 77 and 78 and one or more of the contact projections 772, 774, and 776 is as described above in the exemplary methods of forming exemplary contact holes and exemplary contact projections using exemplary optical masks according to exemplary embodiments of the present invention. Since a sidewall of the contact projection 772, 774, or 776 with respect to a direction perpendicular to a projecting direction of the contact projection 772, 774, or 776 slopes gently, the data wires 67 and 68 can be electrically connected to the pixel electrode 82 and the auxiliary data line terminal 88, respectively, in a stable manner. Therefore, a disconnection does not occur, thereby ensuring better electrical characteristics than would otherwise occur in a contact hole not having one or more of the contact projections 772, 774, and 776.

Next, as shown in FIG. 24, portions of second data metal layers 672 and 682 exposed through the contact holes 77 and 78 are etched. The second data metal layers 672 and 682 may be made of aluminum Al or its alloy, and thus may have poor resistance to chemicals and are easily oxidized. Thus, a disconnection is easily caused and a contact resistance is increased upon direct contact with a pixel electrode forming material such as ITO or IZO, and therefore the second data metal layers 672 and 682 are etched. The second data metal layers 672 and 682 can be selectively etched using a selective etching solution or gas or a time-controllable etching stopper. Thus, this method etches the second data metal layers 672 and 682 after forming contact holes 77 and 78 through the protection film 70.

Finally, referring back to FIGS. 14A and 14B, an ITO film (not shown) is deposited to a thickness of 400 to 500Å and etched by photolithography to thereby form the pixel electrode 82 connected to the drain electrode extension portion 67, the auxiliary gate line terminal 84 connected to the gate line terminal 24, and the auxiliary data line terminal 88 connected to the data line terminal 68. At the same time, the sustain electrode line connection bridge 83 connecting the sustain electrode lines 27 through the contact holes 75 and 76 is also formed.

Meanwhile, prior to depositing the ITO film, pre-heating may be performed under a nitrogen gas to prevent the formation of a metal oxide film on the metal films 24, 27, 67, and 68 exposed through the contact holes 74, 75, 76, 77, and 78, respectively.

Hereinafter, an exemplary method of manufacturing an exemplary TFT array substrate according to still another exemplary embodiment of the present invention using optical masks according to exemplary embodiments of the present invention will be described.

Here, an exemplary TFT array substrate manufactured by the exemplary manufacturing method according to this exemplary embodiment of the present invention has substantially the same structural shape as that manufactured by the exemplary manufacturing method according to the exemplary embodiment shown in FIGS. 14A and 14B.

An exemplary method of manufacturing an exemplary TFT array substrate according to still another exemplary embodiment of the present invention using optical masks according to exemplary embodiments of the present invention will now be described with reference to FIGS. 15A through 16 and 22 through 31.

Gate wires 22, 24 and 26, and sustain electrode line 27 are formed on a substrate 10 and a gate insulating layer 30, an intrinsic amorphous silicon a-Si layer 40, a doped amorphous silicon a-Si layer 50, the first data metal layers 621, 651, 661, 671, and 681 and the second data metal layers 622, 652, 662, 672, and 682, and a photoresist film 110 are sequentially deposited using four masks, as in FIGS. 15A through 16.

Next, as shown in FIG. 25, the photoresist film 110 is exposed to light through a mask and developed to form a photoresist film pattern 112. In this case, all portions of the photoresist film 110 except portions corresponding to data wires are removed.

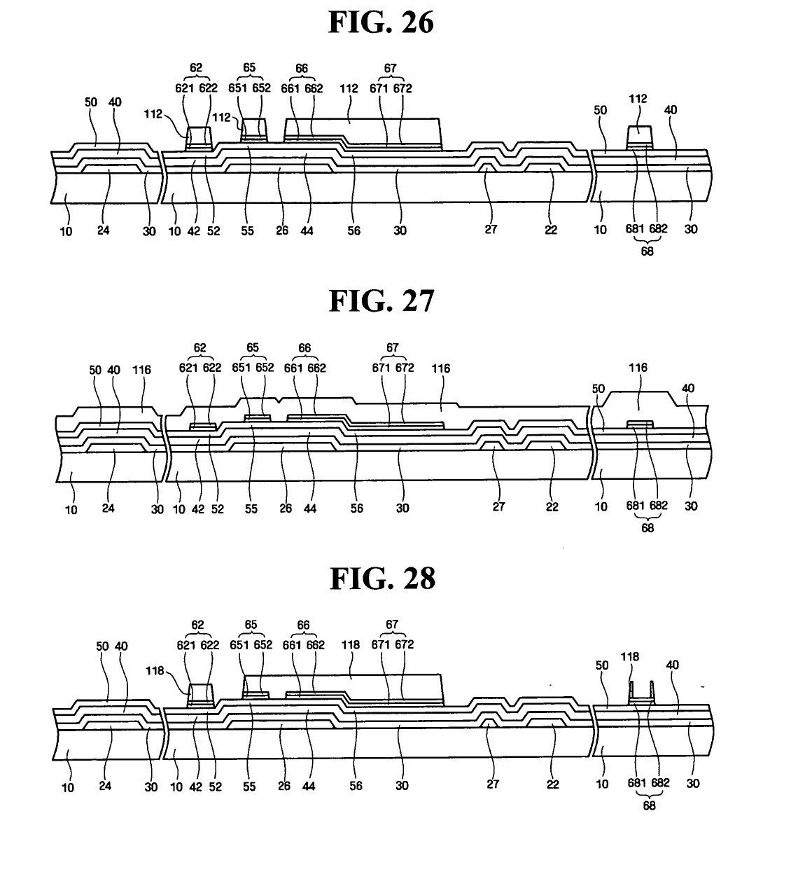

Next, as shown in FIG. 26, the first data metal layers 621, 651, 661, 671, and 681 and the second data metal layers 622, 652, 662, 672, and 682 are etched using the photoresist film pattern 112 as an etching mask. Consequently, exposed portions of the first data metal layers 621, 651, 661, 671, and 681 and the second data metal layers 622, 652, 662, 672, and 682 are removed and thus the underlying doped amorphous silicon layer a-Si 50 is exposed. Then, a residual photoresist film on the second data metal film patterns 622, 642, and 682 is removed by ashing.

Next, as shown in FIG. 27, a photoresist film 116 is again coated on the resultant structure, exposed to light through a mask, and developed, to form a photoresist film pattern 118 as shown in FIG. 28. Then, the intrinsic amorphous silicon a-Si layer 40 and the doped amorphous silicon a-Si layer 50 are etched using the photoresist film pattern 118 as an etching mask. In this case, the doped amorphous silicon a-Si layer 50 and the intrinsic amorphous silicon a-Si layer 40 are etched at the same time by dry etching under the condition that the gate insulating layer 30 is not etched.

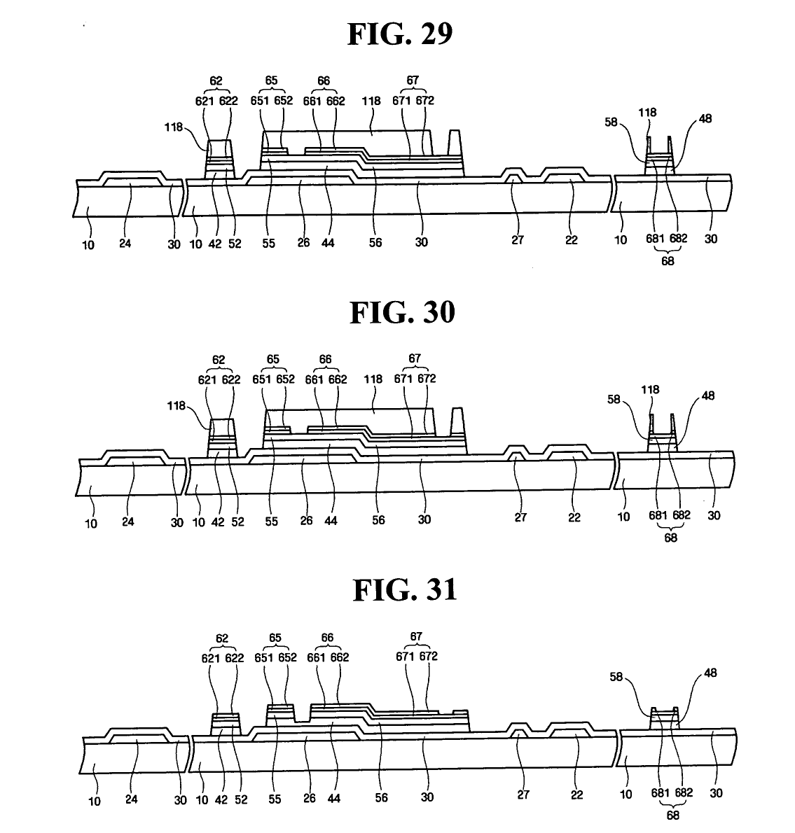

Consequently, as shown in FIG. 29, only portions of the intrinsic amorphous silicon a-Si layer 40 and the doped amorphous silicon a-Si layer 50 corresponding to data wires remain.

Next, as shown in FIG. 30, second data metal layers 672 and 682 are etched using the photoresist pattern 118 as an etching mask. The second data metal layers 672 and 682 are made of aluminum Al or its alloy, and thus have poor resistance to chemicals and are easily oxidized. Thus, a disconnection is easily caused and a contact resistance is increased upon direct contact with a pixel electrode forming material such as ITO or IZO, and therefore the second data metal layers 672 and 682 are etched. The second data metal layers 672 and 682 can be selectively etched using a selective etching solution or gas or a time-controllable etching stopper. Then, a residual photoresist on the second data metal layers 672 and 682 is removed by ashing. Thus, this method etches the second data metal layers 672 and 682 prior to forming contact holes 77 and 78 through a protection film.

Next, as shown in FIG. 31, the doped amorphous silicon a-Si layer 50 is etched using the data wires as an etching mask. In this case, dry etching may be used. When a mixed gas of CF₄ and O₂ is used, a semiconductor pattern 44 made of intrinsic amorphous silicon a-Si can be formed to a uniform thickness. In this case, the semiconductor pattern 44 may have a smaller thickness by partial removal. In this case, the etching must be performed under the condition that the gate insulating layer 30 is not etched.

Consequently, the source electrode 65 and the drain electrode 66 are separated from each other, and formation of ohmic contact layers 55 and 56 is completed.

Referring back to FIGS. 22 through 24, according to a four-mask process, a protection film 70 is formed, contact holes 77, 74, 78, 75, and 76 and contact projections (for example, 772 of FIG. 2A, 774 of FIG. 4A, and 776 of FIG. 6A) are patterned in the protection film 70, and an ITO film (not shown) is deposited to form a pixel electrode 82, an auxiliary gate line terminal 84, an auxiliary data line terminal 88, and a sustain electrode line connection bridge 83.

As described above, when a contact hole and a contact projection are formed on a data metal layer using an optical mask according to the present invention, a pixel electrode can be connected to the data metal layer in a stable manner, thereby ensuring improved electrical characteristics. In addition, a data metal layer and a pixel electrode can be connected to each other in a stable manner, thereby enhancing a high product yield while reducing defective production.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. An optical mask comprising:
a transparent substrate;
a main light-shielding pattern formed on the substrate and defining a substantial shape of a pattern to be transferred onto a surface of a thin film transistor array substrate; and
at least one auxiliary light-shielding pattern projecting toward a transparent region defined by the main light-shielding pattern.

2. The optical mask of claim 1, wherein at least a portion of the at least one auxiliary light-shielding pattern has a width smaller than a limiting resolution of an exposure machine.

3. The optical mask of claim 1, wherein a width of the at least one auxiliary light-shielding pattern decreases toward the transparent region.

4. The optical mask of claim 1, wherein the main light-shielding pattern and the at least one auxiliary light-shielding pattern include an opaque material disposed on the transparent substrate.

5. The optical mask of claim 1, wherein the main light-shielding pattern includes a closed shape defining the transparent region therein, and the at least one auxiliary light-shielding pattern extends from a side of the closed shape towards an interior of the closed shape.

6. The optical mask of claim 1, wherein the at least one auxiliary light-shielding pattern includes a triangular shape, wherein a tip of the triangular shape is positioned within the transparent region defined by the main light-shielding pattern.

7. The optical mask of claim 1, wherein the at least one auxiliary light-shielding pattern includes a stepped structure, wherein a width of an innermost portion of the stepped structure within the transparent region is less than a width of a portion of the stepped structure adjacent the main light-shielding pattern.

8. The optical mask of claim 1, wherein the at least one auxiliary light-shielding pattern includes a rectangular shape.

9. A method of manufacturing a thin film transistor array substrate, the method comprising:
forming a data metal layer on a substrate;
forming an insulating layer on the data metal layer;
patterning a contact hole exposing a portion of the data metal layer and at least one contact projection projecting toward an interior of the contact hole by etching the insulating layer; and
forming a pixel electrode or an auxiliary data line terminal electrically connected to the data metal layer through the contact hole and the contact projection.

10. The method of claim 9, wherein patterning the contact hole and the at least one contact projection is performed using an optical mask comprising a transparent substrate, a main light-shielding pattern formed on the substrate and defining a substantial shape of a pattern to be transferred onto a surface of the thin film transistor array substrate, and at least one auxiliary light-shielding pattern projecting toward a transparent region defined by the main light-shielding pattern.

11. The method of claim 9, wherein patterning at least one contact projection includes patterning at least a portion of the at least one contact projection with a width smaller than a limiting resolution of an exposure machine.

12. The method of claim 9, wherein patterning at least one contact projection includes patterning the contact projection with a tapered angle of smaller than 90 degrees at its sidewall, measured with respect to a direction perpendicular to a projecting direction of the contact projection in the contact hole.

13. The method of claim 9, wherein patterning at least one contact projection includes patterning a width of the contact projection to decrease toward the interior of the contact hole.

14. The method of claim 9, wherein patterning at least one contact projection includes patterning a height of the contact projection to decrease toward the interior of the contact hole.

15. The method of claim 9, wherein patterning at least one contact projection includes patterning the contact projection with a tapered angle decreasing toward the interior of the contact hole at its sidewall, measured with respect to a direction perpendicular to a projecting direction of the contact projection in the contact hole.

16. The method of claim 9, further comprising etching a second layer of the data metal layer prior to forming the pixel electrode or the auxiliary data line terminal, and contacting the pixel electrode or the auxiliary data line terminal to a first layer of the data metal layer.

17. A thin film transistor array substrate comprising:
a data metal layer formed on a substrate;
an insulating layer formed on the data metal layer and including a contact hole exposing a portion of the data metal layer and at least one contact projection projecting toward the contact hole; and
a pixel electrode or an auxiliary data line terminal formed on the insulating layer and electrically connected to the data metal layer through the contact hole and the contact projection.

18. The thin film transistor array substrate of claim 17, wherein at least a portion of the at least one contact projection has a width smaller than a limiting resolution of an exposure machine.

19. The thin film transistor array substrate of claim 17, wherein the at least one contact projection has a tapered angle of smaller than 90 degrees at its sidewall, measured with respect to a direction perpendicular to a projecting direction of the contact projection in the contact hole.

20. The thin film transistor array substrate of claim 17, wherein a width of the at least one contact projection decreases toward an interior of the contact hole.

21. The thin film transistor array substrate of claim 17, wherein a height of the at least one contact projection decreases toward an interior of the contact hole.

22. The thin film transistor array substrate of claim 17, wherein the at least one contact projection has a tapered angle decreasing toward an interior of the contact hole at its sidewall, measured with respect to a direction perpendicular to a projecting direction of the contact projection in the contact hole.

23. The thin film transistor array substrate of claim 17, wherein the at least one contact projection is formed from the insulating layer and integral with a periphery of the contact hole.
